(19) United States
(12) Patent Application Publication
(10) Pub. No.: US 2024/0088282 A1
(43) Pub. Date: Mar. 14, 2024

(54) SEMICONDUCTOR DEVICE AND SEMICONDUCTOR MODULE

(71) Applicant: ROHM CO., LTD., Kyoto-shi (JP)

(72) Inventor: Tsuyoshi TACHI, Kyoto-shi (JP)

(73) Assignee: ROHM CO., LTD., Kyoto-shi (JP)

(21) Appl. No.: 18/457,368

(22) Filed: Aug. 29, 2023

(30) Foreign Application Priority Data
Sep. 8, 2022 (JP) 2022-143077

(51) Int. Cl. H01L 29/778; H01L 23/29; H01L 23/31; H01L 29/20; H01L 29/417; H01L 29/94

(52) U.S. Cl. CPC H01L 29/7786; H01L 23/293; H01L 23/3114; H01L 29/2003; H01L 29/41775; H01L 29/94

(57) ABSTRACT

A semiconductor device includes a semiconductor substrate, a transistor formed on the semiconductor substrate, an insulation layer arranged on the semiconductor substrate, a source pad formed on a head surface of the insulation layer and electrically connected to the source electrode, a drain pad formed on the head surface of the insulation layer and electrically connected to the drain electrode, a gate pad formed on the head surface of the insulation layer and connected to the gate electrode, a specified pad formed on the head surface of the insulation layer, and a capacitor. The capacitor includes a source-side electrode, electrically connected to the source electrode, and a specified electrode, electrically connected to the specified pad and arranged facing the source-side electrode.

### CROSS-REFERENCE TO RELATED APPLICATION

This application is based upon and claims the benefit of priority of the prior Japanese Patent Application No. 2022-143077, filed on Sep. 8, 2022, the entire contents of which are incorporated herein by reference.

### BACKGROUND

### Field

The present disclosure is related to a semiconductor device and a semiconductor module.

### Description of Related Art

A transistor formed by a semiconductor device may be a GaN transistor (for example, refer to Japanese Laid-Open Patent Publication No. 2017-37967).

### BRIEF DESCRIPTION OF THE DRAWINGS

FIG. 1 is a schematic plan view showing a semiconductor device of a first embodiment.

FIG. 2 is a schematic cross-sectional view of the semiconductor device taken along line F2-F2 in FIG. 1.

FIG. 3 is an enlarged view showing section F3 of FIG. 1 in detail.

FIG. 4 is an enlarged view showing section F4 of FIG. 3.

FIG. 5 is a schematic cross-sectional view taken along line F5-F5 in FIG. 4 and showing part of the semiconductor device.

FIG. 6 is a schematic cross-sectional view taken along line F6-F6 in FIG. 4 and showing part of the semiconductor device.

FIG. 7 is a schematic cross-sectional view taken along line F7-F7 in FIG. 1 and showing part of the semiconductor device.

FIG. 8 is a schematic plan view showing a semiconductor module of the first embodiment.

FIG. 9 is a schematic cross-sectional view showing part of a semiconductor device of a second embodiment.

FIG. 10 is a schematic plan view showing a semiconductor device of a third embodiment.

FIG. 11 is a schematic plan view showing a semiconductor module of a modified example.

FIG. 12 is a schematic cross-sectional view showing part of a semiconductor device in a modified example.

Throughout the drawings and the detailed description, the same reference characters refer to the same elements. The drawings may not be to scale, and the relative size, proportions, and depiction of elements in the drawings may be exaggerated for clarity, illustration, and convenience.

### DETAILED DESCRIPTION

This description provides a comprehensive understanding of the methods, apparatuses, and/or systems described. Modifications and equivalents of the methods, apparatuses, and/or systems described are apparent to one of ordinary skill in the art. Sequences of operations are exemplary, and may be changed as apparent to one of ordinary skill in the art, with the exception of operations necessarily occurring in a certain order. Descriptions of functions and constructions that are well known to one of ordinary skill in the art may be omitted.

Exemplary embodiments may have different forms, and are not limited to the examples described. However, the examples described are thorough and complete, and convey the full scope of the disclosure to one of ordinary skill in the art.

In this specification, “at least one of A and B” should be understood to mean “only A, only B, or both A and B.”

Embodiments of a semiconductor device and a semiconductor module will be described below with reference to the drawings.

Elements in the figures are illustrated for simplicity and clarity and have not necessarily been drawn to scale. To facilitate understanding, hatching lines may not be shown in the cross-sectional drawings. The accompanying drawings illustrate exemplary embodiments in accordance with the present disclosure and are not intended to limit the present disclosure.

This detailed description provides a comprehensive understanding of the methods, apparatuses, and/or systems described. Exemplary embodiments may have different forms, and are not limited to the examples described.

### First Embodiment

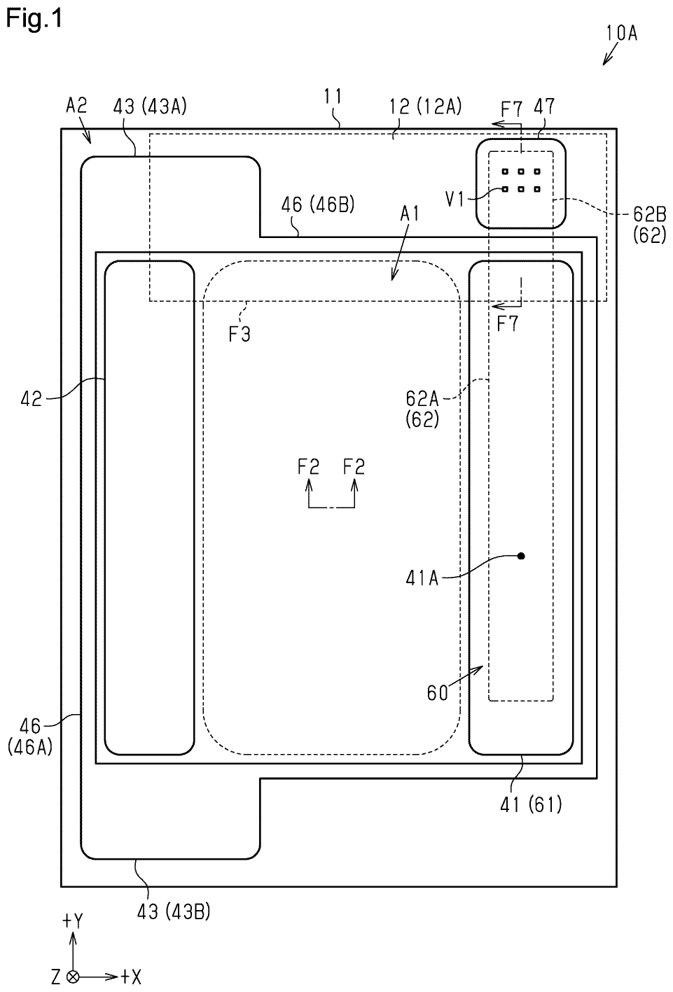

With reference to FIGS. 1 to 8, the configuration of a semiconductor device and a semiconductor module in accordance with a first embodiment will now be described.

General Configuration of Semiconductor Device

FIG. 1 schematically shows the planar structure of a semiconductor device 10A in accordance with the first embodiment. In this specification, the X-axis, Y-axis, and Z-axis are orthogonal to one another as shown in FIG. 1. The term “plan view” as used in this specification is a view of the semiconductor device 10A taken in the Z-direction. Further, in FIG. 1, which shows the semiconductor device 10A, the +Z direction corresponds to the upward direction, the −Z direction corresponds to the downward direction, the +X direction corresponds to the rightward direction, and the −X direction corresponds to the leftward direction.

Referring to FIG. 1, the semiconductor device 10A includes a semiconductor substrate 11, a transistor T (not shown) formed on the semiconductor substrate 11, and an insulation layer 12 arranged on the semiconductor substrate 11.

The semiconductor substrate 11 may be, for example, a silicon (Si) substrate. A silicon carbide (SiC) substrate, a gallium nitride (GaN) substrate, or a sapphire substrate may be used instead of a Si substrate. The semiconductor substrate 11 may have a thickness of, for example, between 200 μm and 1500 μm, inclusive.

In the description hereafter, thickness will mean the dimension in the Z-direction indicated in FIG. 1 unless otherwise specified. Unless otherwise indicated, the term “plan view” will refer to a view taken from above in the thickness direction of the semiconductor substrate 11, that is, a view taken from above in the Z-axis of the semiconductor device 10A.

The insulation layer 12 may be composed of a material containing one of, for example, silicon nitride (SiN), silicon dioxide (SiO₂), silicon oxynitride (SiON), alumina (Al₂O₃), aluminum nitride (AlN), and aluminum oxynitride (AlON). In one example, the insulation layer 12 is formed from a material containing SiN.

The semiconductor device 10A includes an active region A1, defined by the central portion of the semiconductor substrate 11 in plan view, and a peripheral region A2, defined by the peripheral portion of the semiconductor substrate 11 and surrounding the active region A1 in a frame-shaped manner. The active region A1 is where the transistor T is formed, and the peripheral region A2 is where the transistor T is not formed.

Transistor

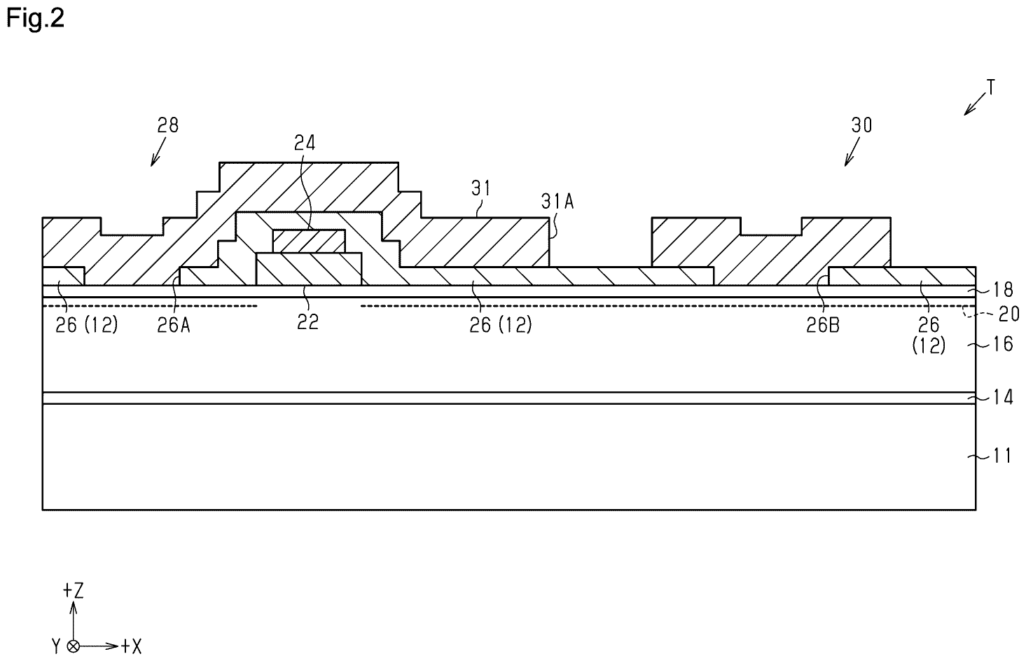

FIG. 2 is a schematic cross-sectional view of the semiconductor device 10A taken along line F2-F2 in FIG. 1 and showing one example of the cross-sectional structure of the transistor T. Hatching lines are not shown in certain parts to aid understanding. Further, the insulation layer 12 arranged on the transistor T is not shown in the drawing.

The transistor T shown in FIG. 2 is a high-electron-mobility transistor (HEMT) that uses a nitride semiconductor. The transistor T includes a buffer layer 14 formed on the semiconductor substrate 11, an electron transit layer 16 formed on the buffer layer 14, and an electron supply layer 18 formed on the electron transit layer 16.

The buffer layer 14 may be formed from any material that limits wafer warping or cracking that would be caused by a difference in coefficient of thermal expansion between the semiconductor substrate 11 and the electron transit layer 16. Further, the buffer layer 14 may include one or more nitride semiconductor layers. The buffer layer 14 may include, for example, at least one of an aluminum nitride (AlN) layer, an aluminum gallium nitride (AlGaN) layer, and a graded AlGaN layer of different aluminum (Al) compositions. For example, the buffer layer 14 may be a single film of AlN, a single film of AlGaN, a film having an AlGaN/GaN superlattice structure, a film having an AlN/AlGaN superlattice structure, or a film having an AlN/GaN superlattice structure.

In one example, the buffer layer 14 includes a first buffer layer, which is an AlN layer formed on the semiconductor substrate 11, and a second buffer layer, which is an AlGaN layer formed on the AlN layer (first buffer layer). The first buffer layer may be an AlN layer having a thickness of 200 nm, and the second buffer layer may be a graded AlGaN layer having a thickness of 300 nm. To reduce leakage current in the buffer layer 14, part of the buffer layer 14 may include an impurity so that regions other than the outermost part of the buffer layer 14 are semi-insulative. In this case, the impurity may be, for example, carbon (C) or iron (Fe). The concentration of the impurity may be, for example, 4×10¹⁶ cm⁻³ or greater.

The electron transit layer 16 is composed of a nitride semiconductor. The electron transit layer 16 may be, for example, a GaN layer. The electron transit layer 16 may have a thickness of, for example, between 0.5 μm and 2 inclusive. To reduce leakage current in the electron transit layer 16, part of the electron transit layer 16 may include an impurity so that regions other than the outermost layer of the electron transit layer 16 are semi-insulative. In this case, the impurity may be, for example, carbon (C). The concentration of the impurity may be, for example, 4×10¹⁶ cm⁻³ or greater. The electron transit layer 16 may include GaN layers of different impurity concentrations, for example, a carbon-doped GaN layer and a non-doped GaN layer. In this case, the carbon-doped GaN layer is formed on the buffer layer 14. The carbon-doped GaN layer may have a thickness of between 0.5 μm and 2 inclusive. The carbon-doped GaN layer may have a carbon concentration of between 5×10¹⁷ cm⁻³ and 9×10¹⁹ cm⁻³, inclusive. The non-doped GaN layer is formed on the carbon-doped GaN layer. The non-doped GaN layer may have a thickness of between 0.05 μm and 0.4 μm inclusive. The non-doped GaN layer contacts the electron supply layer 18. In one example, the electron transit layer 16 includes a carbon-doped GaN layer having a thickness of 0.4 μm and a non-doped GaN layer having a thickness of 0.4 The carbon-doped GaN layer has a carbon concentration of approximately 2×10¹⁹ cm⁻³. The electron supply layer 18 has a larger band gap than the electron transit layer 16. The electron supply layer 18 may be, for example, an AlGaN layer. A nitride semiconductor will have a larger band gap as the Al composition increases. Thus, the electron supply layer 18, which is an AlGaN layer, has a larger band gap than the electron transit layer 16, which is a GaN layer. In one example, the electron supply layer 18 is composed of AlₓGa₁₋ₓN. Thus, the electron supply layer 18 is an AlₓGa₁₋ₓN layer, where x is 0<x<0.4 and, more preferably, 0.1<x<0.3. The electron supply layer 18 may have a thickness of, for example, between 5 nm and 20 nm, inclusive.

The electron transit layer 16 and the electron supply layer 18 have bulk regions with different lattice constants. Thus, the electron transit layer 16 and the electron supply layer 18 are lattice-mismatched junctions. The spontaneous polarization of the electron transit layer 16 and the electron supply layer 18 and the piezoelectric polarization resulting from the compression stress received by the heterojunction of the electron transit layer 16 cause the energy level of the conduction band of the electron transit layer 16 to be lower than the Fermi level in the proximity of the heterojunction interface between the electron transit layer 16 and the electron supply layer 18. Thus, two-dimensional electron gas (2DEG) 20 spreads in the electron transit layer 16 at a location proximate to (e.g., distanced by approximately a few nanometers from interface) the heterojunction interface of the electron transit layer 16 and the electron supply layer 18.

The transistor T includes a gate layer 22 formed on the electron supply layer 18, a gate electrode 24 formed on the gate layer 22, and an insulation layer 26 covering the electron supply layer 18, the gate layer 22, and the gate electrode 24. The insulation layer 26 includes a source opening 26A and a drain opening 26B located at opposite sides of the gate layer 22 with respect to the X-direction in plan view. The X-direction is the direction in which the source opening 26A and the drain opening 26B are separated.

The gate layer 22 has a smaller band gap than the electron supply layer 18 and is composed of a nitride semiconductor containing an acceptor impurity. The gate layer 22 may be formed from any material having a smaller band gap than the electron supply layer 18, which is an AlGaN layer. In one example, the gate layer 22 is a GaN layer (p-type GaN layer) doped with an acceptor impurity. The acceptor impurity may contain at least one of zinc (Zn), magnesium (Mg), and carbon (C). The maximum concentration of the acceptor impurity in the gate layer 22 is, for example, between 1×10¹⁸ cm⁻³ and 1×10²⁰ cm⁻³, inclusive.

The acceptor impurity included in the gate layer 22 raises the energy level of the electron transit layer 16 and the electron supply layer 18. Thus, the energy level of the conduction band of the electron transit layer 16 is substantially the same as or greater than the Fermi level in the proximity of the heterojunction interface between the electron transit layer 16 and the electron supply layer 18 in the region underneath the gate layer 22. Accordingly, at zero-bias when voltage is not applied to the gate electrode 24, the 2DEG 20 is not formed in the electron transit layer 16 in the region underneath the gate layer 22. The 2DEG 20 is formed in the electron transit layer 16 at regions other than the region underneath the gate layer 22.

In this manner, the gate layer 22, which is doped with the acceptor impurity, depletes the 2DEG 20 in the region underneath the gate layer 22. This results in the transistor T being default off, or normally off. The application of an appropriate on-voltage to the gate electrode 24 will form a channel with the 2DEG 20 in the electron transit layer 16 in the region underneath the gate electrode 24 to electrically connect the source and drain.

The cross-sectional shape of the gate layer 22 is not particularly limited. For example, the gate layer 22 may have a rectangular, trapezoidal, or ridged cross section taken along an XZ plane in FIG. 2.

The gate electrode 24 is composed of one or more metal layers. In one example, the gate electrode 24 is a titanium nitride (TiN) layer. Alternatively, the gate electrode 24 may be formed by a first metal layer of a material containing Ti and a second metal layer stacked on the first metal layer and formed from a material containing TiN. The gate electrode 24 and the gate layer 22 may form a Schottky junction. The gate electrode 24 may be formed in a smaller region than the gate layer 22 in plan view. The gate electrode 24 has a thickness of, for example, between 50 nm and 200 nm, inclusive.

The insulation layer 26 is formed on the electron supply layer 18. The insulation layer 26 covers the electron supply layer 18. The insulation layer 26 is a part of the insulation layer 12 arranged on the semiconductor substrate 11. More specifically, the insulation layer 26 is the part of the insulation layer 12 located in the active region A1. The insulation layer 26 is a passivation layer. Part of the insulation layer 26 covers the gate layer 22 and the gate electrode 24.

The source opening 26A and the drain opening 26B are each separated from the gate layer 22. The gate layer 22 is located between the source opening 26A and the drain opening 26B. The gate layer 22 is located closer to the source opening 26A than the drain opening 26B in the X-direction. Thus, the distance between the gate layer 22 and the drain opening 26B in the X-direction is longer than the distance between the gate layer 22 and the source opening 26A in the X-direction.

The transistor T further includes a source electrode 28, contacting the electron supply layer 18 through the source opening 26A, and a drain electrode 30, contacting the electron supply layer 18 through the drain opening 26B.

The source electrode 28 and the drain electrode 30 are formed by one or more metal layers of, for example, Ti, Al, AlCu, TiN, or the like. The source electrode 28 and the drain electrode 30 are in ohmic contact with the 2DEG 20 through the source opening 26A and the drain opening 26B, respectively.

The transistor T further includes a field plate electrode 31 formed on the insulation layer 26. The field plate electrode 31 extends in at least part of the region between the gate layer 22 and the drain electrode 30 in plan view. The field plate electrode 31 is separated from the drain electrode 30. Thus, the field plate electrode 31 includes, for example, an end 31A located between the drain electrode 30 (drain opening 26B) and the gate layer 22 in plan view.

The field plate electrode 31 is electrically connected to the source electrode 28. In one example, as shown in FIG. 2, the field plate electrode 31 is continuous with the source electrode 28. In this case, the field plate electrode 31 is formed integrally with the source electrode 28. In the integrated electrode, the source electrode 28 may include at least the part embedded in the source opening 26A of the insulation layer 26, and the field plate electrode 31 may include the remaining part. The field plate electrode 31 functions to limit electric field concentration near the end of the gate electrode 24 at zero-bias when gate voltage is not applied to the gate electrode 24.

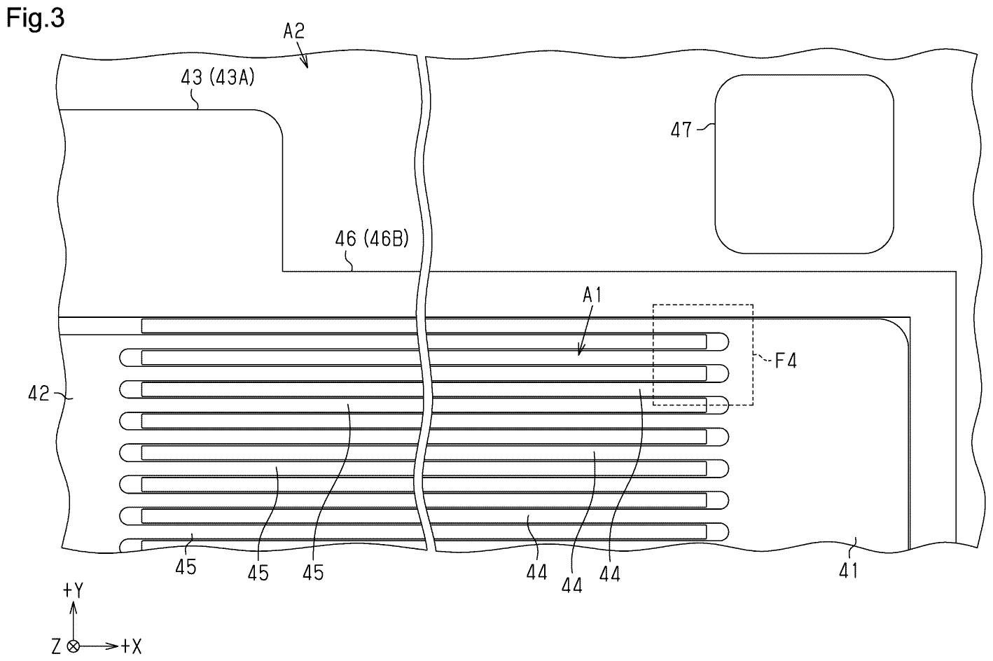

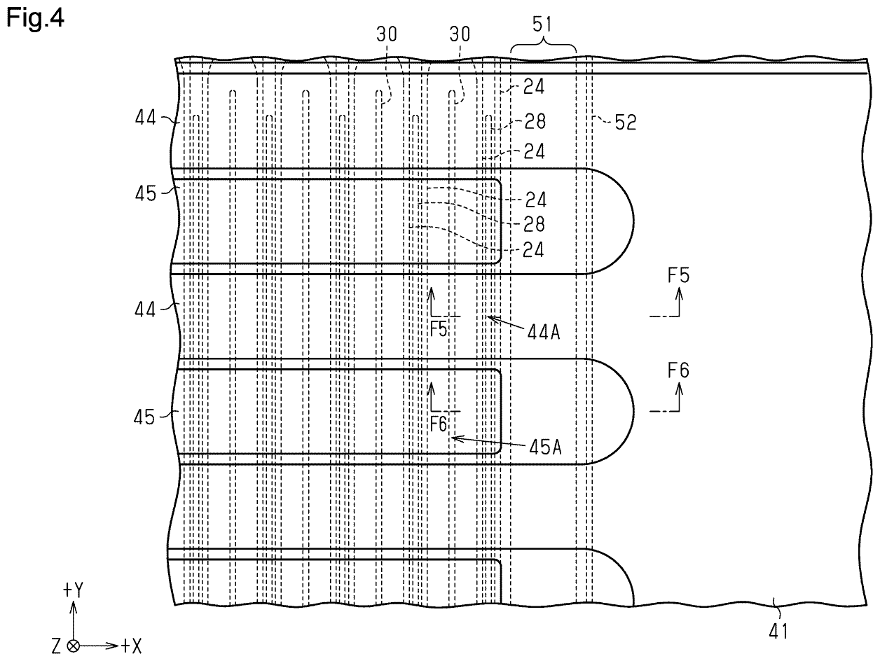

FIG. 3 is an enlarged view showing section F3 of FIG. 1 in detail, and FIG. 4 is an enlarged view showing section F4 of FIG. 3. FIG. 4 shows, in broken lines, the part of the source electrode 28 embedded in the source opening 26A, the part of the drain electrode 30 embedded in the drain opening 26B, and the gate electrode 24.

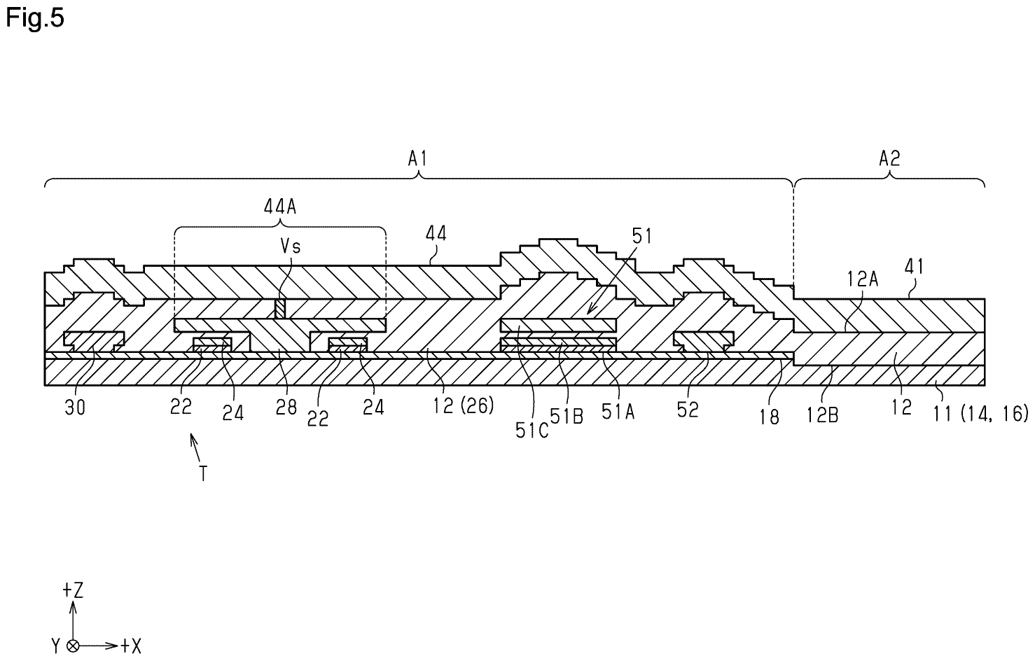

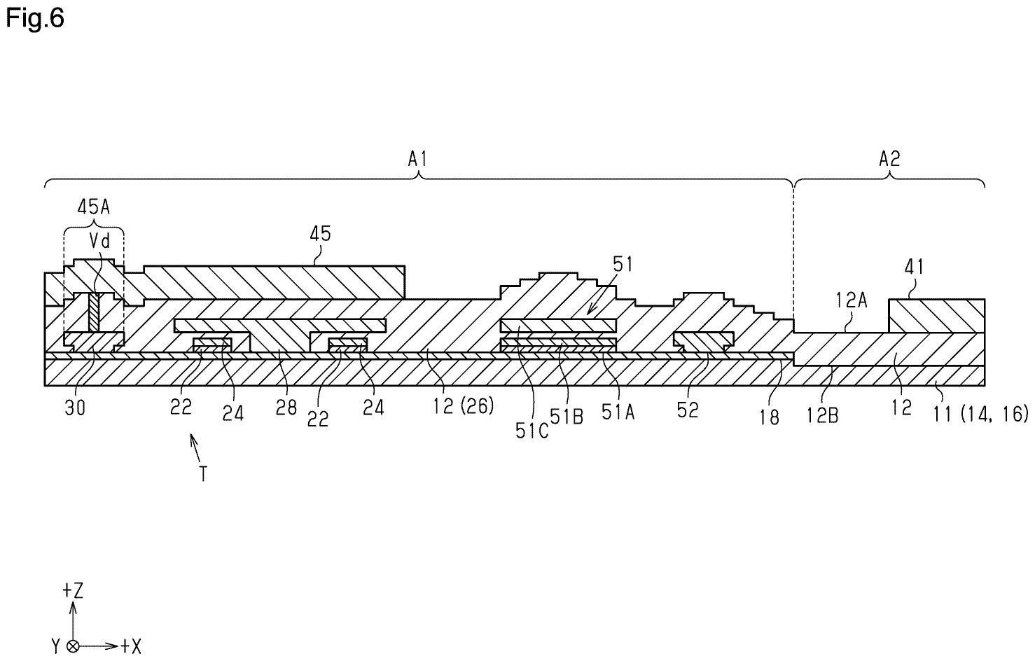

As shown in FIG. 4, the source electrode 28, the drain electrode 30, and the gate electrode 24 each extend in the Y-direction in plan view. In further detail, the cross-sectional structure of the HEMT shown in FIG. 2 extends continuously in the Y-direction. Structures of the HEMT described above extending in the Y-direction are arranged next to each other in the X-direction. Although not shown in FIG. 4, the two ends of the gate electrode 24 extend out of the active region A1 and are located in the peripheral region A2. As shown in FIGS. 5 and 6, in the peripheral region A2, the electron supply layer 18 is not formed, and the insulation layer 12 is formed on the electron transit layer 16. FIGS. 5 and 6 show the semiconductor substrate 11, the buffer layer 14, and the electron transit layer 16 as a single layer.

In the present embodiment, the direction in which the source electrode 28, the drain electrode 30, and the gate electrode 24 extend is the Y-direction, or a first direction, and the direction orthogonal to the Y-direction is the X-direction, or a second direction. Hereafter, the Y-direction may be referred to as the first direction, and the X-direction may be referred to as the second direction.

Source Pad, Drain Pad, Gate Pad, and Surrounding Structure

As shown in FIG. 1, the semiconductor device 10A includes a source pad 41, a drain pad 42, and a gate pad 43 that are formed on a head surface 12A of the insulation layer 12. The source pad 41, the drain pad 42, and the gate pad 43 may be formed from any conductive material including at least one of, for example, copper (Cu), aluminum (Al), an AlCu alloy, tungsten (W), titanium (Ti), and titanium nitride (TiN).

The source pad 41 is an electrode pad electrically connected to the source electrode 28 of the transistor T. The source pad 41 is located on the head surface 12A of the insulation layer 12 in the peripheral region A2 next to the active region A1 at the +X-direction side of the active region A1. The source pad 41 is rectangular and elongated in the Y-direction in plan view. The source pad 41 and the active region A1 are formed over substantially the same range in the Y-direction.

The drain pad 42 is an electrode pad electrically connected to the drain electrode 30 of the transistor T. The drain pad 42 is located on the head surface 12A of the insulation layer 12 in the peripheral region A2 next to the active region A1 at the −X-direction side of the active region A1. The drain pad 42 is rectangular and elongated in the Y-direction in plan view. The drain pad 42 and the active region A1 are formed over substantially the same range in the Y-direction. The source pad 41 and the drain pad 42 are separated from each other in the X-direction and located at opposite sides of the active region A1.

The gate pad 43 is an electrode pad electrically connected to the gate electrode 24 of the transistor T. The gate pad 43 includes a first gate pad 43A and a second gate pad 43B.

The first gate pad 43A is located on the head surface 12A of the insulation layer 12 in the peripheral region A2 next to the active region A1 at the +Y-direction side of the active region A1. Further, the first gate pad 43A is located closer to the drain pad 42 than the source pad 41. In the example shown in FIG. 1, the first gate pad 43A is located at the +Y-direction side of the drain pad 42. The first gate pad 43A is separated from the drain pad 42.

The second gate pad 43B is located on the head surface 12A of the insulation layer 12 in the peripheral region A2 next to the active region A1 at the −Y-direction side of the active region A1. Further, the second gate pad 43B is located closer to the drain pad 42 than the source pad 41. In the example shown in FIG. 1, the second gate pad 43B is located at the −Y-direction side of the drain pad 42. The second gate pad 43B is separated from the drain pad 42. The first gate pad 43A and the second gate pad 43B are separated from each other in the Y-direction at opposite sides of the drain pad 42.

The first gate pad 43A and the second gate pad 43B are rectangular and elongated in the X-direction in plan view. The first gate pad 43A and the second gate pad 43B extend further from the drain pad 42 in the −X-direction. The first gate pad 43A and the second gate pad 43B extend further from the drain pad 42 in the +X-direction.

Referring to FIGS. 1 and 3, the semiconductor device 10A includes source interconnections 44 extending from the source pad 41, drain interconnections 45 extending from the drain pad 42, and a gate interconnection 46 extending from the gate pad 43. FIG. 1 does not show the source interconnections 44 and the drain interconnections 45.

Each of the source interconnections 44 extends from the edge of the source pad 41 at the side closer to the active region A1 (edge at −X-direction side) toward the drain pad 42 in the X-direction. Each of the source interconnections 44 extends across the peripheral region A2 and the active region A1. The distal end of each of the source interconnections 44 is located in the active region A1. The source interconnections 44 are arranged at equal intervals in the Y-direction. Further, each of the source interconnections 44 is formed integrally with the source pad 41.

Each of the drain interconnections 45 extends from the edge of the drain pad 42 at the side closer to the active region A1 (edge at +X-direction side) toward the source pad 41 in the X-direction. Each of the drain interconnections 45 extends across the peripheral region A2 and the active region A1. The distal end of each of the drain interconnections 45 is located in the active region A1. The drain interconnections 45 are arranged at equal intervals in the Y-direction. In the active region A1, the source interconnections 44 and the drain interconnections 45 are arranged alternately in the Y-direction. The source interconnections 44 are separated from the drain interconnections 45 in the Y-direction. Each of the drain interconnections 45 is formed integrally with the drain pad 42.

As shown in FIG. 1, the gate interconnection 46 includes a first gate interconnection 46A and a second gate interconnection 46B. The first gate interconnection 46A and the second gate interconnection 46B connect the first gate pad 43A and the second gate pad 43B. The first gate interconnection 46A and the second gate interconnection 46B, as a whole, surround the active region A1, the source pad 41, and the drain pad 42 in a frame-shaped manner.

The first gate interconnection 46A is located on the head surface 12A of the insulation layer 12 in the peripheral region A2 at the −X-direction side of the drain pad 42. The first gate interconnection 46A extends in the Y-direction from the first gate pad 43A, at the part of located toward the −X-direction from the drain pad 42, to the second gate pad 43B, at the part located toward the −X-direction from the drain pad 42.

The second gate interconnection 46B extends on the head surface 12A of the insulation layer 12 in a U-shaped manner surrounding the active region A1 and the source pad 41. The second gate interconnection 46B has one end connected to the first gate pad 43A and another end connected to the second gate pad 43B. The gate interconnection 46 is formed integrally with the gate pad 43.

FIG. 5 is a schematic cross-sectional view of the semiconductor device 10A taken along line F5-F5 in FIG. 4. FIG. 6 is a schematic cross-sectional view of the semiconductor device 10A taken along line F6-F6 in FIG. 4. In FIGS. 5 and 6, the cross-sectional structure of the transistor T is shown in a simplified manner as compared with the cross-sectional structure shown in FIG. 2.

As shown in FIGS. 4 and 5, each source interconnection 44 includes a section 44A overlapping the source electrode 28 in the Z-direction. In the section 44A where the source interconnection 44 and the source electrode 28 overlap, the insulation layer 12 located between the source interconnection 44 and the source electrode 28 includes a via Vs extending through the insulation layer 12 and electrically connecting the source interconnection 44 and the source electrode 28.

As shown in FIGS. 4 and 6, each drain interconnection 45 includes a section 45A overlapping the drain electrode 30 in the Z-direction. In the section 45A where the drain interconnection 45 and the drain electrode 30 overlap, the insulation layer 12 located between the drain interconnection 45 and the drain electrode 30 includes a via Vd extending through the insulation layer 12 and electrically connecting the drain interconnection 45 and the drain electrode 30.

As shown in FIGS. 4 to 6, the peripheral part of the active region A1 includes a first peripheral guard ring 51 and a second peripheral guard ring 52 that have the form of a square frame and surround the central part of the active region A1.

One example of the first peripheral guard ring 51 includes a semiconductor layer 51A arranged on the electron supply layer 18 in contact with the electron supply layer 18, a first conductive layer 51B arranged on the semiconductor layer 51A in contact with the semiconductor layer 51A, and a second conductive layer 51C embedded in the insulation layer 12 on the first conductive layer 51B. The semiconductor layer 51A is, for example, composed of the same material as the gate layer 22. The first conductive layer 51B is, for example, composed of the same material as the gate electrode 24. The second conductive layer 51C is, for example, composed of the same material as one or both of the source electrode 28 and the drain electrode 30.

The second peripheral guard ring 52 is located further outward from the first peripheral guard ring 51 in the active region A1 and surrounds the first peripheral guard ring 51. One example of the second peripheral guard ring 52 is a conductive layer arranged on the electron supply layer 18 in contact with the electron supply layer 18. The second peripheral guard ring 52 is, for example, composed of the same material as one or both of the source electrode 28 and the drain electrode 30.

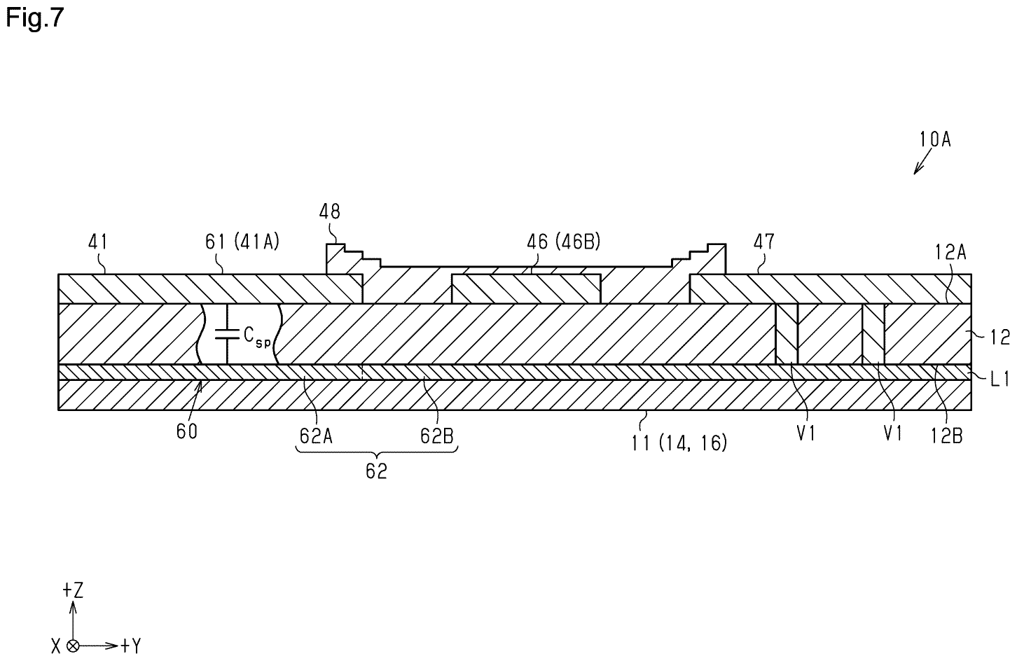

FIG. 7 is a schematic cross-sectional view of the semiconductor device 10A taken along line F7-F7 in FIG. 1. FIG. 7 shows the structure of the insulation layer 12 in a simplified manner. As shown in FIG. 7, a protective film 48 is arranged on the head surface 12A of the insulation layer 12. The protective film 48 covers the surface (upper surface) of the semiconductor device 10A at the side where the pads are formed. The protective film 48 includes sections entirely or partially exposing the source pad 41, the drain pad 42, the gate pad 43, and a specified pad 47, which will be described later.

In the example shown in FIG. 7, the protective film 48 covers the second gate interconnection 46B and the head surface 12A of the insulation layer 12 between the specified pad 47 and the source pad 41. Further, the protective film 48 may include a part that partially covers the upper surface of the specified pad 47 and a part that partially covers the upper surface of the source pad 41. The protective film 48 may be composed of, for example, an insulative material such as polyimide. The drawings other than FIG. 7 do not show the protective film 48.

Specified Pad and Capacitor

As shown in FIGS. 1 and 7, the semiconductor device 10A includes the specified pad 47, which is formed on the head surface 12A of the insulation layer 12, and a capacitor 60. The specified pad 47 and the capacitor 60 are arranged in the peripheral region A2.

In the example shown in FIG. 1, the specified pad 47 is located closer to the source pad 41 than the gate pad 43 on the head surface 12A of the insulation layer 12 in the peripheral region A2. The specified pad 47 is located on the head surface 12A of the insulation layer 12 next to the source pad 41 at the +Y-direction side of the source pad 41 with the second gate interconnection 46B located in between.

In one example, the specified pad 47 is square in plan view. Instead of being square, the specified pad 47 may be rectangular, circular, or elliptic. In one example, the specified pad 47 has a smaller width in the X-direction than the source pad 41. The width of the specified pad 47 in the X-direction may be greater than that of the source pad 41 or substantially equal to that of the source pad 41.

The capacitor 60 includes a source-side electrode 61, electrically connected to the source electrode 28, and a specified electrode 62, electrically connected to the specified pad 47 and arranged facing the source-side electrode 61. The source-side electrode 61 is formed by the source pad 41 electrically connected to the source electrode 28. The potential at the source-side electrode 61 of the capacitor 60 is a source potential.

As shown in FIG. 7, the specified electrode 62 is a third conductive layer L1 formed on a back surface 12B of the insulation layer 12. The insulation layer 12 includes the head surface 12A and the back surface 12B located at the opposite side of the head surface 12A. The head surface 12A of the insulation layer 12 is the surface (upper surface) of the insulation layer 12 facing the +Z-direction at the side opposite the semiconductor substrate 11. The back surface 12B of the insulation layer 12 is the surface (lower surface) of the insulation layer 12 facing the −Z-direction, or the semiconductor substrate 11.

The third conductive layer L1 may be formed from any conductive material including at least one of, for example, copper (Cu), aluminum (Al), an AlCu alloy, tungsten (W), titanium (Ti), and titanium nitride (TiN). In one example, the third conductive layer L1 is composed of the same material as the gate electrode 24, for example, titanium nitride (TiN). In this case, the third conductive layer L1 is patterned and formed simultaneously with the gate electrode 24. In another example, the third conductive layer L1 is composed of the same material as one or both of the source electrode 28 and the drain electrode 30, for example, an AlCu alloy. In this case, the third conductive layer L1 may be patterned and formed simultaneously with one or both of the source electrode 28 and the drain electrode 30.

As shown in FIGS. 1 and 7, the specified electrode 62 includes an opposing portion 62A, facing the source pad 41 with the insulation layer 12 located in between, and a connecting portion 62B, connecting the opposing portion 62A and the specified pad 47.

In the example shown in FIG. 1, the opposing portion 62A is rectangular and elongated in the Y-direction along the source pad 41 in plan view. The opposing portion 62A has a smaller width in the X-direction than the source pad 41. The width of the opposing portion 62A in the X-direction may be greater than that of the source pad 41. In this case, the opposing portion 62A extends beyond one or two sides of the source pad 41 in the X-direction in plan view. The opposing portion 62A may have a distal end (end at side opposite to specified pad 47) located outward from the source pad 41 in the Y-direction or overlapping the source pad 41, in plan view. The opposing portion 62A does not have to be rectangular in plan view.

The connecting portion 62B extends from the opposing portion 62A in the +Y-direction and is partially located below the specified pad 47. The specified electrode 62, which includes the opposing portion 62A and the connecting portion 62B, extends across both of the source pad 41 and the specified pad 47. The connecting portion 62B includes a section overlapping the specified pad 47 in the Z-direction. In the section where the connecting portion 62B and the specified pad 47 overlap, the insulation layer 12 located between the connecting portion 62B and the specified pad 47 includes vias V1 extending through the insulation layer 12 and electrically connecting the connecting portion 62B and the specified pad 47.

The potential at the specified electrode 62 of the capacitor 60 is equal to the potential at the specified pad 47 and varied in accordance with the voltage applied to the specified pad 47. As will be described in detail later, the specified pad 47 is electrically connected to the gate pad 43 when necessary. In this case, the specified electrode 62 is electrically connected by the specified pad 47 and the gate pad 43 to the gate electrode 24. Thus, in this case, the potential at the specified electrode 62 is the gate potential.

The source-side electrode 61 includes an opposed portion 41A where the source pad 41 opposes the opposing portion 62A of the specified electrode 62. The opposed portion 41A may be part of the source pad 41 or the entire source pad 41. When the entire source pad 41 is the opposed portion 41A, the opposing portion 62A of the specified electrode 62 is formed with a size that is greater than or equal to the size of the source pad 41 in plan view and arranged facing the entire source pad 41. Further, as described above, the source pad 41 is electrically connected to the source electrode 28 by the via Vs formed in the insulation layer 12.

The capacitor 60 includes the opposing portion 62A of the specified electrode 62 formed by the third conductive layer L1, the source-side electrode 61 that is the source pad 41, and the insulation layer 12 located between the opposing portion 62A and the source pad 41. The capacitor 60 has a capacitance between the opposing portion 62A and the source pad 41. In the description hereafter, the capacitance of the capacitor 60 will be referred to as the specified capacitance Cₛₚ.

The specified capacitance Cₛₚ may be calculated from equation (1).

Cₛₚ=ε×(S/d) (1)

In equation (1), S represents the opposing area over which the source-side electrode 61 and the specified electrode 62 face each other. Further, d represents the inter-electrode distance between the source-side electrode 61 and the specified electrode 62, and ε represents the relative permittivity of the insulation layer 12 located between the source-side electrode 61 and the specified electrode 62. Accordingly, the specified capacitance Cₛₚ may be varied by changing one or more of the opposing area S, the inter-electrode distance d, and relative permittivity c of the insulation layer 12. The relative permittivity of the insulation layer 12 may be changed by changing the type of the insulation layer 12.

The opposing area S is, for example, between 0.02 mm² and 0.4 mm², inclusive. The opposing area S is the area of the opposed portion 41A in the source pad 41 facing the opposing portion 62A of the specified electrode 62 in plan view. The inter-electrode distance d is, for example, between 50 nm and 3000 nm, inclusive. In the present embodiment, the inter-electrode distance d is equal to the thickness of the insulation layer 12 in the peripheral region A2.

Semiconductor Module

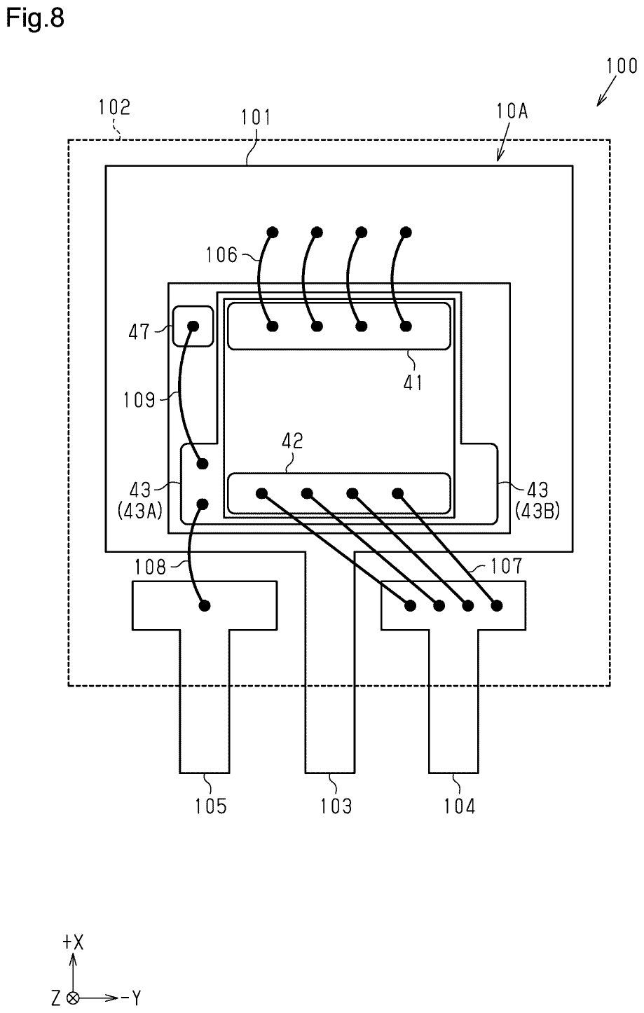

With reference to FIG. 8, one example of the configuration of a semiconductor module 100 including the semiconductor device 10A will now be described. FIG. 8 is a schematic plan view showing the interconnection structure of the semiconductor module 100.

The semiconductor module 100 includes a die pad 101, the semiconductor device 10A mounted on the die pad 101, and an encapsulation resin 102 encapsulating the semiconductor device 10A.

The die pad 101 is rectangular. The die pad 101 is formed from, for example, copper (Cu) or an alloy containing copper. The encapsulation resin 102 is formed from, for example, an insulative resin material, such as an epoxy resin, an acrylic resin, or a phenol resin.

The semiconductor module 100 includes a source lead 103, a drain lead 104, and a gate lead 105 that are partially exposed from the encapsulation resin 102. The source lead 103 is formed integrally with the die pad 101.

Further, the semiconductor module 100 includes source wires 106, drain wires 107, and a gate wire 108. The source wires 106 connect the die pad 101 and the source pad 41. The drain wires 107 connect the drain lead 104 and the drain pad 42. The gate wire 108 connects the gate lead 105 and the gate pad 43 (first gate pad 43A). The source wires 106, the drain wires 107, and the gate wire 108 are each encapsulated in the encapsulation resin 102.

The semiconductor module 100 further includes a specified wire 109 connecting the specified pad 47 and the gate pad 43 (first gate pad 43A). The specified wire 109 is encapsulated in the encapsulation resin 102. The specified wire 109 may be omitted when not necessary.

Each of the source wires 106, the drain wires 107, the gate wire 108, and the specified wire 109 is a bonding wire formed from, for example, a conductive material, such as gold (Au), Al, and Cu, by a wire bonding device. In the present embodiment, the wires are formed from the same material (e.g., Cu). At least one of the wires may be formed from a material differing from that of the other wires.

Operation

The operation of the semiconductor device 10A in accordance with the first embodiment will now be described.

The semiconductor device 10A includes the capacitor 60. The capacitor 60 includes the source-side electrode 61 and the specified electrode 62, which faces the source-side electrode 61 with the insulation layer 12 located in between. The source-side electrode 61 of the capacitor 60 is the source pad 41 electrically connected to the source electrode 28. The specified electrode 62 of the capacitor 60 is electrically connected to the specified pad 47. The semiconductor device 10A including the capacitor 60 with the above configuration may be used in a first application that electrically disconnects the specified pad 47 and the gate pad 43 and a second application that electrically connects the specified pad 47 and the gate pad 43.

In the first application, the specified pad 47 is electrically disconnected from the gate pad 43. In further detail, the specified pad 47 is electrically disconnected from other electrode pads so as to have null potential (floating state). Consequently, the potential at the source-side electrode 61 of the capacitor 60 is a source potential, and the potential at the specified electrode 62 of the capacitor 60 is a null potential. In this case, the specified capacitance Cₛₚ of the capacitor 60 does not affect the gate-source parasitic capacitance C_{gs} of the semiconductor device 10A. Accordingly, the gate-source parasitic capacitance C_{gs} will be the original capacitance (hereafter, referred to as the basic capacitance) that is unaffected by the capacitor 60, that is, the capacitance based on the structure of the semiconductor device 10A.

In the second application, the specified pad 47 and the gate pad 43 are electrically connected by the specified wire 109. Thus, the potential at the source-side electrode 61 of the capacitor 60 is a source potential, and the potential at the specified electrode 62 of the capacitor 60 is a gate potential. In this case, the specified capacitance Cₛₚ of the capacitor 60 will be the capacitance produced between the gate electrode 24 and the source electrode 28. That is, the specified capacitance Cₛₚ of the capacitor 60 is added to the gate-source parasitic capacitance C_{gs} of the semiconductor device 10A. Thus, the gate-source parasitic capacitance C_{gs} is increased from the basic capacitance by the specified capacitance Cₛₚ of the capacitor 60. In the second application, the gate-source parasitic capacitance C_{gs} is greater than that of the first application.

In this manner, the semiconductor device 10A may be used in two applications having a different gate-source parasitic capacitance C_{gs}. Accordingly, with the configuration of the present embodiment, the gate-source parasitic capacitance of the semiconductor device 10A may be varied when necessary without changing the design of the semiconductor device 10A by choosing whether to connect the specified pad 47 and the gate pad 43.

The drain-source voltage of the transistor is steeply varied when performing high-speed switching with the transistor, such as in an inverter circuit formed by a bridge circuit or a non-insulative synchronous rectification converter circuit. When the drain-source voltage varies steeply, the gate-source voltage of the transistor will rise. In this case, the transistor that is in an off-state may be erroneously turned on. Such a situation is referred to as a self-turn-on.

A self-turn-on occurs when voltage is suddenly applied between the drain and source of the transistor that is in an off-state. In this case, the application of a gate voltage exceeding the threshold voltage to the gate-source parasitic capacitance C_{gs} in accordance with the ratio C_{gd}/C_{gs} of the gate-drain parasitic capacitance C_{gd} to the gate-source parasitic capacitance C_{gs} will turn on the transistor.

In the semiconductor device that forms a transistor, to avoid a self-turn-on, the gate-source parasitic capacitance C_{gs} may be increased to decrease the ratio C_{gd}/C_{gs}. When the gate-source parasitic capacitance C_{gs} is increased, the charge amount required for gate driving will increase. This will lower the power efficiency. Thus, it is preferred that the semiconductor devices designed with an increased gate-source parasitic capacitance C_{gs} are selectively applied at portions where self-turn-on tends to occur. In this case, however, there will be a need to prepare different semiconductor devices that are designed to have a different gate-source parasitic capacitance C_{gs}.

In the semiconductor device 10A of the present embodiment, the second application in which the gate-source parasitic capacitance C_{gs} is relatively large may be selectively used at, for example, a portion where self-turn-on tends to occur. The first application in which the gate-source parasitic capacitance C_{gs} is relatively small may be selectively used at, for example, a portion where the occurrence of a self-turn-on is limited and priority is given to improvement in power efficiency.

In one example, the semiconductor device 10A may be applied to a high-side switch and a low-side switch in a non-insulative synchronous rectification converter circuit. In a non-insulative synchronous rectification converter circuit, a self-turn-on occurs more easily in a low-side switch than a high-side switch. Thus, the semiconductor device 10A of the second application in which the gate-source parasitic capacitance C_{gs} is relatively large is used as the low-side switch. The semiconductor device 10A of the first application in which the gate-source parasitic capacitance C_{gs} is relatively small is used as the high-side switch.

Consequently, in the low-side switch, the gate-source parasitic capacitance C_{gs} will be greater than the normal capacitance. This will avoid the occurrence of a self-turn-on. In the high-side switch, the gate-source parasitic capacitance C_{gs} will be the normal capacitance. This will allow the semiconductor device 10A to maintain the expected power efficiency. In this manner, the gate-source parasitic capacitance C_{gs} of the semiconductor device 10A applied to a low-side switch can be different from that of the semiconductor device 10A applied to a high-side switch, while the semiconductor devices 10A applied to the low-side switch and the high-side switch can be communized.

Advantages

The semiconductor device 10A of the first embodiment has the advantages described below.

(1-1) The semiconductor device 10A includes the semiconductor substrate 11, the transistor T formed on the semiconductor substrate 11 and including the source electrode 28, the drain electrode 30, and the gate electrode 24, the insulation layer 12 arranged on the semiconductor substrate 11, the source pad 41 formed on the head surface 12A of the insulation layer 12 and electrically connected to the source electrode 28, the drain pad 42 formed on the head surface 12A of the insulation layer 12 and electrically connected to the drain electrode 30, the gate pad 43 formed on the head surface 12A of the insulation layer 12 and connected to the gate electrode 24, the specified pad 47 formed on the head surface 12A of the insulation layer 12, and the capacitor 60. The capacitor 60 includes the source-side electrode 61, electrically connected to the source electrode 28, and the specified electrode 62, electrically connected to the specified pad 47 and arranged facing the source-side electrode 61.

When manufacturing the semiconductor module 100 including the semiconductor device 10A, the specified pad 47 may be connected to or disconnected from the gate pad 43. When the specified pad 47 and the gate pad 43 are disconnected, the gate-source parasitic capacitance C_{gs} of the semiconductor device 10A will be the basic capacitance. When the specified pad 47 and the gate pad 43 are connected, the gate-source parasitic capacitance C_{gs} will be increased from the basic capacitance by the capacitance of the capacitor 60 (specified capacitance Cₛₚ). In this manner, the gate-source parasitic capacitance may be varied without changing the design of the semiconductor device 10A by either connecting or disconnecting the specified pad 47 and the gate pad 43.

This configuration allows for application to both of a semiconductor device in which a large gate-source parasitic capacitance C_{gs} is preferred and a semiconductor device in which a small gate-source parasitic capacitance C_{gs} is preferred. Thus, this configuration is advantageous when using the same semiconductor device for different gate-source parasitic capacitances C_{gs}.

(1-2) The specified electrode 62 includes the opposing portion 62A facing the source pad 41 with the insulation layer 12 located in between. The source-side electrode 61 includes the opposed portion 41A formed by the source pad 41 where the source pad 41 faces the opposing portion 62A.

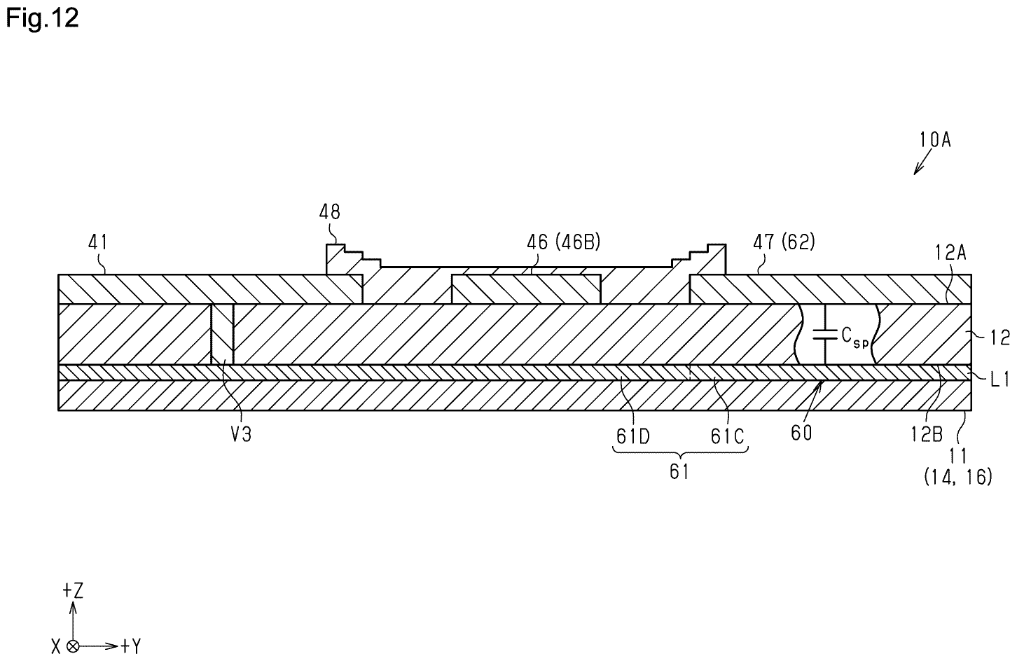

This configuration allows the capacitor 60 to be located between the source pad 41 and the semiconductor substrate 11. Thus, the arrangement of the capacitor 60 will not enlarge the semiconductor device 10A. With this configuration, adjustment of the range in which the opposing portion 62A of the specified electrode 62 is formed allows the specified capacitance Cₛₚ of the capacitor 60 to be easily adjusted. Further, in this configuration, the opposing area S of the source-side electrode 61 and the specified electrode 62 is greater than when the capacitor 60 is arranged in the semiconductor device 10A at a portion other than between the source pad 41 and the semiconductor substrate 11 (refer to description of FIG. 12 below).

(1-3) The specified electrode 62 includes the connecting portion 62B electrically connecting the opposing portion 62A and the specified pad 47. The specified electrode 62 extends across both of the source pad 41 and the specified pad 47 in plan view. This facilitates connection of the specified electrode 62 of the capacitor 60, located between the source pad 41 and the semiconductor substrate 11, to the specified pad 47.

(1-4) The semiconductor device 10A includes the vias V1 that extend through the insulation layer 12 between the connecting portion 62B and the specified pad 47 and electrically connect the connecting portion 62B and the specified pad 47. This configuration allows the specified electrode 62 of the capacitor 60, which is located between the source pad 41 and the semiconductor substrate 11, to be connected to the specified pad 47 with a simple structure.

(1-5) The opposing portion 62A is formed on the back surface 12B of the insulation layer 12. This configuration allows the insulation layer 12, located between the source pad 41 and the semiconductor substrate 11, to be entirely used by the capacitor 60 in the thickness direction. Thus, the specified capacitance Cₛₚ of the capacitor 60 can be increased.

(1-6) The specified pad 47 is located closer to the source pad 41 than the gate pad 43 on the head surface 12A of the insulation layer 12. In this configuration, the specified pad 47 is located near the source pad 41. This facilitates connection of the specified electrode 62 of the capacitor 60, which is located between the source pad 41 and the semiconductor substrate 11, to the specified pad 47. Further, the connecting portion 62B of the specified electrode 62 does not have to be enlarged and may have a simple shape.

(1-7) The gate pad 43 is located closer to the drain pad 42 than the source pad 41 on the head surface 12A of the insulation layer 12. In this configuration, the gate pad 43 is located at a position separated from the source pad 41 thereby forming a space where the specified pad 47 can be arranged near the source pad 41 in the peripheral region A2. This facilitates arrangement of the specified pad 47 near the source pad 41.

(1-8) The transistor T includes the electron transit layer 16 composed of a nitride semiconductor, the electron supply layer 18 formed on the electron transit layer 16 and composed of a nitride semiconductor having a larger band gap than the electron transit layer 16, the gate layer 22 formed on part of the electron supply layer 18 and composed of a nitride semiconductor containing an acceptor impurity, the gate electrode 24 formed on the gate layer 22, and the source electrode 28 and the drain electrode 30 contacting the electron supply layer 18. The gate layer 22 is located between the source electrode 28 and the drain electrode 30 on the electron supply layer 18.

In the transistor T (HEMT) of this configuration, the moving speed of electrons is higher than other transistors. Thus, when used as a high-speed switching element, self-turn-on tends to occur. In the semiconductor device 10A in which the transistor T is a HEMT, the capacitor 60 increases the gate-source parasitic capacitance C_{gs}. This is effective for restricting self-turn-on.

(1-9) The semiconductor module 100 includes the semiconductor device 10A and the encapsulation resin 102 encapsulating the semiconductor device 10A. This configuration obtains the semiconductor module 100 including the semiconductor device 10A.

(1-10) The semiconductor module 100 includes the specified wire 109 connecting the specified pad 47 and the gate pad 43. This configuration increases the gate-source parasitic capacitance C_{gs} of the semiconductor device 10A. This avoids the occurrence of a self-turn-on in the semiconductor device 10A.

(1-11) The specified pad 47 of the semiconductor module 100 is electrically disconnected from the gate pad 43. In this configuration, the gate-source parasitic capacitance C_{gs} of the semiconductor device 10A is not increased by the capacitor 60 in the semiconductor device 10A. Thus, the semiconductor device 10A avoids decreases in the power efficiency that would be caused by the capacitor 60.

### Second Embodiment

A semiconductor device 10B of the second embodiment differs from the first embodiment in the structure of the specified electrode 62 in the capacitor 60. Otherwise, the structure is the same as the first embodiment. Elements that are the same as the corresponding elements in the first embodiment will not be described in detail. The description will focus on differences from the first embodiment.

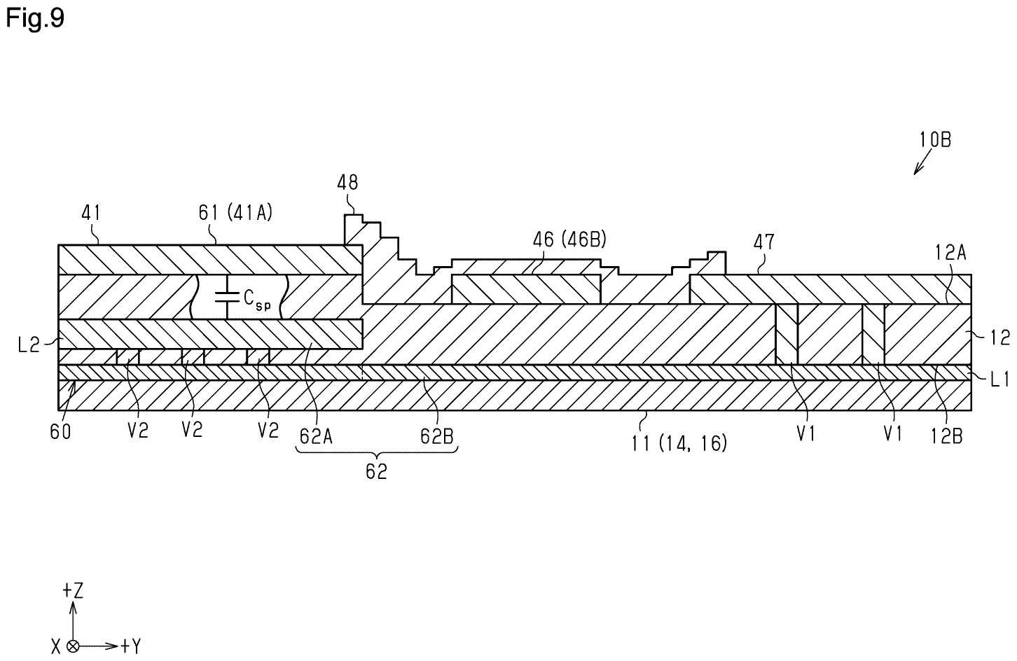

FIG. 9 is a schematic cross-sectional view showing part of the semiconductor device 10B of the second embodiment. FIG. 9 shows a portion corresponding to the portion shown in FIG. 7 in the first embodiment.

As shown in FIG. 9, the third conductive layer L1 is formed on the back surface 12B of the insulation layer 12. Further, a fourth conductive layer L2 embedded in the insulation layer 12 is formed between the source pad 41 and the semiconductor substrate 11. The insulation layer 12, located between the third conductive layer L1 and the fourth conductive layer L2 includes vias V2 extending through the insulation layer 12 and electrically connecting the third conductive layer L1 and the fourth conductive layer L2.

The opposing portion 62A of the specified electrode 62 in the present embodiment is formed by the fourth conductive layer L2. Thus, the opposing portion 62A is an embedded conductive layer embedded in the insulation layer 12. The connecting portion 62B of the specified electrode 62 is formed by the third conductive layer L1 and the vias V2.

Accordingly, the capacitor 60 includes the opposing portion 62A of the specified electrode 62 formed by the fourth conductive layer L2, the source-side electrode 61 that is the source pad 41, and the insulation layer 12 located between the opposing portion 62A and the source pad 41. In this case, part of the insulation layer 12 in the thickness direction, that is, the part located between the head surface 12A of the insulation layer 12 and the fourth conductive layer L2, forms the capacitor 60. The capacitor 60 has a capacitance between the opposing portion 62A and the source pad 41.

The connecting portion 62B, which is formed by the third conductive layer L1, extends across both of the opposing portion 62A, which is formed by the fourth conductive layer L2, and the specified pad 47 in plan view. Further, the connecting portion 62B is electrically connected by the vias V1 to the specified pad 47.

The third conductive layer L1 may be formed from any conductive material including at least one of, for example, copper (Cu), aluminum (Al), an AlCu alloy, tungsten (W), titanium (Ti), and titanium nitride (TiN). In one example, the third conductive layer L1 is composed of the same material as the gate electrode 24, for example, titanium nitride (TiN). In this case, the third conductive layer L1 is patterned and formed simultaneously with the gate electrode 24.

The fourth conductive layer L2 may be formed from any conductive material including at least one of, for example, copper (Cu), aluminum (Al), an AlCu alloy, tungsten (W), titanium (Ti), and titanium nitride (TiN). One example of the fourth conductive layer L2 is composed of the same material as one or both of the source electrode 28 and the drain electrode 30, for example, an AlCu alloy. In this case, the fourth conductive layer L2 may be patterned and formed simultaneously with one or both of the source electrode 28 and the drain electrode 30.

Advantages

As described above, the semiconductor device 10B of the second embodiment has the same advantage as the semiconductor device 10A of the first embodiment except for advantage (1-5). The semiconductor device 10B of the second embodiment has the advantages described below.

(2-1) The opposing portion 62A is an embedded conductive layer (fourth conductive layer L2) embedded in the insulation layer 12. In this configuration, when another layer, such as an interconnection layer, is arranged on the back surface 12B of the insulation layer 12 between the source pad 41 and the semiconductor substrate 11, the opposing portion 62A may also be arranged in a range overlapping the other layer in plan view. This increases the freedom of design for the opposing portion 62A.

### Third Embodiment

A semiconductor device 10C of the third embodiment differs from the first embodiment in the arrangement of the specified pad 47 and the structure of the specified electrode 62 in the capacitor 60. Otherwise, the structure is the same as the first embodiment. Elements that are the same as the corresponding elements in the first embodiment will not be described in detail. The description will focus on differences from the first embodiment.

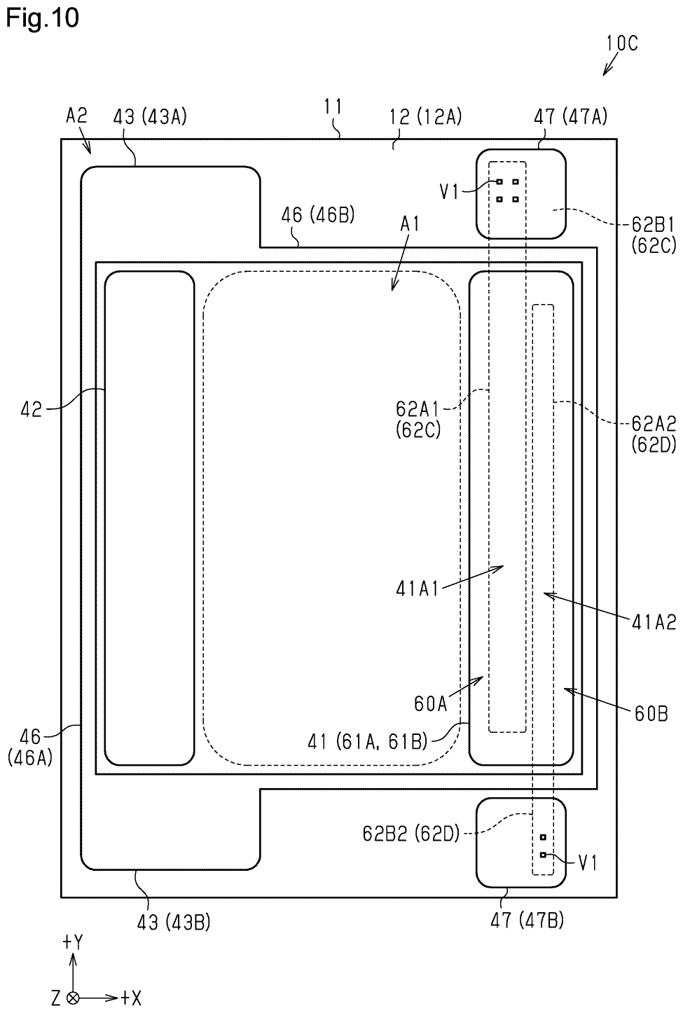

As shown in FIG. 10, the specified pad 47 of the semiconductor device 10C includes a first specified pad 47A and a second specified pad 47B that are formed, separated from each other, on the head surface 12A of the insulation layer 12. In the example shown in FIG. 10, the first specified pad 47A and the second specified pad 47B are located in the peripheral region A2 closer to the source pad 41 than the gate pad 43 on the head surface 12A of the insulation layer 12.

The first specified pad 47A and the second specified pad 47B are arranged sandwiching the source pad 41 and separated from each other in the Y-direction in which the source pad 41 extends on the head surface 12A of the insulation layer 12. In detail, the first specified pad 47A is located on the head surface 12A of the insulation layer 12 next to the source pad 41 at the +Y-direction side of the source pad 41 with the second gate interconnection 46B located in between. The second specified pad 47B is located on the head surface 12A of the insulation layer 12 next to the source pad 41 at the −Y-direction side of the source pad 41 with the second gate interconnection 46B located in between. In the example shown in FIG. 10, the first gate pad 43A of the gate pad 43 is arranged next to the first specified pad 47A in the X-direction. The second gate pad 43B of the gate pad 43 is arranged next to the second specified pad 47B in the X-direction.

In one example, the first specified pad 47A and the second specified pad 47B are square in plan view. Instead of being square, the specified pad 47 may be rectangular, circular, or elliptic.

In one example, the first specified pad 47A and the second specified pad 47B have a smaller width in the X-direction than the source pad 41. The width of the first specified pad 47A and the second specified pad 47B in the X-direction may be greater than that of the source pad 41 or substantially equal to that of the source pad 41. The width of the first specified pad 47A in the X-direction may be the same as or differ from that of the second specified pad 47B.

The capacitor 60 of the semiconductor device 10C includes a first capacitor 60A and a second capacitor 60B.

The first capacitor 60A includes a first source-side electrode 61A, electrically connected to the source electrode 28, and a first specified electrode 62C, electrically connected to the first specified pad 47A and arranged facing the first source-side electrode 61A. The first source-side electrode 61A is formed by the source pad 41, which is electrically connected to the source electrode 28. The potential at the first source-side electrode 61A of the first capacitor 60A is a source potential. The first specified electrode 62C may have the same configuration as the first embodiment or the second embodiment.

The first specified electrode 62C includes a first opposing portion 62A1, facing the source pad 41 with the insulation layer 12 located in between, and a first connecting portion 62B1, connecting the first opposing portion 62A1 and the first specified pad 47A. In the example shown in FIG. 10, the first opposing portion 62A1 is rectangular and elongated in the Y-direction along the source pad 41 in plan view.

The first connecting portion 62B1 extends from the first opposing portion 62A1 in the +Y-direction and is partially located below the first specified pad 47A. The first specified electrode 62C, including the first opposing portion 62A1 and the first connecting portion 62B1, extends across both of the source pad 41 and the first specified pad 47A in plan view.

The first connecting portion 62B1 includes a section overlapping the first specified pad 47A in the Z-direction. In the section where the first connecting portion 62B1 and the first specified pad 47A overlap, the insulation layer 12 located between the first connecting portion 62B1 and the first specified pad 47A includes the vias V1 extending through the insulation layer 12 and electrically connecting the first connecting portion 62B1 and the first specified pad 47A.

The first source-side electrode 61A includes a first opposed portion 41A1 where the source pad 41 opposes the first opposing portion 62A1 of the first specified electrode 62C. The first opposed portion 41A1 is part of the source pad 41.

The first capacitor 60A includes the first opposing portion 62A1 of the first specified electrode 62C, the first source-side electrode 61A that is the source pad 41, and the insulation layer 12 located between the first opposing portion 62A1 and the source pad 41. The first capacitor 60A has a capacitance between the first opposing portion 62A1 and the source pad 41.

The second capacitor 60B includes a second source-side electrode 61B, electrically connected to the source electrode 28, and a second specified electrode 62D electrically connected to the second specified pad 47B and arranged facing the second source-side electrode 61B. The second source-side electrode 61B is formed by the source pad 41, which is electrically connected to the source electrode 28. The first source-side electrode 61A and the second source-side electrode 61B are formed from the same source pad 41. The potential at the second source-side electrode 61B of the second capacitor 60B is the source potential. The second specified electrode 62D may have the same configuration as the first embodiment or the second embodiment.

The second specified electrode 62D includes a second opposing portion 62A2, facing the source pad 41 with the insulation layer 12 located in between, and a second connecting portion 62B2, connecting the second opposing portion 62A2 and the second specified pad 47B. The first opposing portion 62A1 of the first specified electrode 62C and the second opposing portion 62A2 of the second specified electrode 62D are arranged so as not to overlap each other in plan view.

The second connecting portion 62B2 extends from the second opposing portion 62A2 in the −Y-direction and is partially located below the second specified pad 47B. The second specified electrode 62D, including the second opposing portion 62A2 and the second connecting portion 62B2, extends across both of the source pad 41 and the second specified pad 47B in plan view.

The second connecting portion 62B2 includes a section overlapping the second specified pad 47B in the Z-direction. In the section where the second connecting portion 62B2 and the second specified pad 47B overlap, the insulation layer 12 located between the second connecting portion 62B2 and the second specified pad 47B includes the vias V1 extending through the insulation layer 12 and electrically connecting the second connecting portion 62B2 and the second specified pad 47B.

The second source-side electrode 61B includes a second opposed portion 41A2 where the source pad 41 opposes the second opposing portion 62A2 of the second specified electrode 62D. The second opposed portion 41A2 is part of the source pad 41. The first opposed portion 41A1 of the first source-side electrode 61A and the second opposed portion 41A2 of the second source-side electrode 61B are arranged so as not to overlap each other in plan view.

The second capacitor 60B includes the second opposing portion 62A2 of the second specified electrode 62D, the second source-side electrode 61B that is the source pad 41, and the insulation layer 12 located between the second opposing portion 62A2 and the source pad 41. The second capacitor 60B has a capacitance between the second opposing portion 62A2 and the source pad 41.

The first capacitor 60A may have a capacitance (hereafter, referred to as the first specified capacitance Cₛₚ₁) that is set freely, and the second capacitor 60B may have a capacitance (hereafter, referred to as the second specified capacitance Cₛₚ₂) that is set freely. For example, the first specified capacitance Cₛₚ₁ may be greater than the second specified capacitance Cₛₚ₂, smaller than the second specified capacitance Cₛₚ₂, or equal to the second specified capacitance Cₛₚ₂. When the first specified capacitance Cₛₚ₁ is greater than the second specified capacitance Cₛₚ₂, the capacitance ratio (Cₛₚ₁/Cₛₚ₂) is, for example, between 2 and 100, inclusive.

The first specified capacitance Cₛₚ₁ may be varied by changing one or more of the opposing area S1 of the first source-side electrode 61A (source pad 41) and the first specified electrode 62C, the inter-electrode distance d1 between the first source-side electrode 61A (source pad 41) and the first specified electrode 62C, and the relative permittivity c of the insulation layer 12. The second specified capacitance Cₛₚ₂ may be varied by changing one or more of the opposing area S2 of the second source-side electrode 61B (source pad 41) and the second specified electrode 62D, the inter-electrode distance d2 between the second source-side electrode 61B (source pad 41) and the second specified electrode 62D, and the relative permittivity c of the insulation layer 12. Accordingly, the relative relationship of the first specified capacitance Cₛₚ₁ and the second specified capacitance Cₛₚ₂ can be adjusted by setting different opposing areas, setting different inter-electrode distances between the first capacitor 60A and the second capacitor 60B, or setting different opposing areas and different inter-electrode distances for the first capacitor 60A and the second capacitor 60B.

The opposing areas may be set differently by having, for example, the first opposing portion 62A1 of the first specified electrode 62C differ in shape from the second opposing portion 62A2 of the second specified electrode 62D. The inter-electrode distances may be set differently by, for example, arranging the first opposing portion 62A1 and the second opposing portion 62A2 at different positions in the Z-direction. For example, the first opposing portion 62A1 is formed by the back surface 12B of the insulation layer 12 (opposing portion 62A of first embodiment), and the second opposing portion 62A2 is embedded in the insulation layer 12 (opposing portion 62A of second embodiment).

In the example shown in FIG. 10, the opposing area of the first capacitor 60A is greater than the opposing area of the second capacitor 60B so that the first specified capacitance Cₛₚ₁ is greater than the second specified capacitance Cₛₚ₂.

In detail, each of the first specified electrode 62C and the second specified electrode 62D is rectangular and elongated in the Y-direction in plan view. The first opposing portion 62A1 of the first specified electrode 62C and the second opposing portion 62A2 of the second specified electrode 62D are arranged next to each other in the X-direction in a range overlapping the source pad 41. The first opposing portion 62A1 of the first specified electrode 62C has a length in the Y-direction that is the same as that of the second opposing portion 62A2 of the second specified electrode 62D.

The first opposing portion 62A1 of the first specified electrode 62C has a length in the X-direction that is greater than that of the second opposing portion 62A2 of the second specified electrode 62D. Accordingly, the opposing area of the first specified electrode 62C and the first source-side electrode 61A (source pad 41) is greater than the opposing area of the second specified electrode 62D and the second source-side electrode 61B (source pad 41). Thus, the first specified capacitance Cₛₚ₁ is greater than the second specified capacitance Cₛₚ₂. The inter-electrode distances of the first capacitor 60A and the second capacitor 60B are the same, and the relative permittivity of the insulation layer 12 is the same.

The planar shape and arrangement of the first opposing portion 62A1 and the second opposing portion 62A2 may be set so that the opposing area of the first specified electrode 62C and the opposing area of the second specified electrode 62D have a certain relationship. For example, the first opposing portion 62A1 and the second opposing portion 62A2 may have the same length in the X-direction and different lengths in the Y-direction. The first opposing portion 62A1 and the second opposing portion 62A2 do not have to be rectangular in plan view and may be, for example, L-shaped. The arrangement of the first opposing portion 62A1 and the second opposing portion 62A2 may be changed, for example, so as to be arranged next to each other in the Y-direction.

When manufacturing the semiconductor module 100 that includes the semiconductor device 10C, the specified pad 47 (first specified pad 47A and second specified pad 47B) is electrically connected to the gate pad 43 when necessary. For example, the first specified pad 47A is connected by the specified wire 109 to the first gate pad 43A, and the second specified pad 47B is connected by the specified wire 109 to the second gate pad 43B. The first specified pad 47A and the second gate pad 43B may be connected, and the second specified pad 47B and the first gate pad 43A may be connected.

Operation

The operation of the semiconductor device 10C in accordance with the third embodiment will now be described.

In the same manner as the first embodiment, the semiconductor device 10C may be used in a first application that electrically disconnects the specified pad 47 (first specified pad 47A and second specified pad 47B) and the gate pad 43 and a second application that electrically connects the specified pad 47 and the gate pad 43. Further, in the second application of the semiconductor device 10C, the gate pad 43 may be connected to the first specified pad 47A and the second specified pad 47B differently in a number of modes.

In the first mode, the gate pad 43 and the first specified pad 47A are connected, and the gate pad 43 and the second specified pad 47B are disconnected. In this case, the gate-source parasitic capacitance C_{gs} is increased from the basic capacitance by the first specified capacitance Cₛₚ₁ of the first capacitor 60A.

In the second mode, the gate pad 43 and the first specified pad 47A are disconnected, and the gate pad 43 and the second specified pad 47B are connected. In this case, the gate-source parasitic capacitance C_{gs} is increased from the basic capacitance by the second specified capacitance Cₛₚ₂ of the second capacitor 60B.

In the third mode, the gate pad 43 is connected to both of the first specified pad 47A and the second specified pad 47B. For example, the first gate pad 43A is connected to the first specified pad 47A, and the second gate pad 43B is connected to the second specified pad 47B. Alternatively, one of the first gate pad 43A and the second gate pad 43B is connected to one of the first specified pad 47A and the second specified pad 47B, and the first specified pad 47A and the second specified pad 47B are connected. In this case, the gate-source parasitic capacitance C_{gs} is increased from the basic capacitance by the total of the first specified capacitance Cₛₚ₁ of the first capacitor 60A and the second specified capacitance Cₛₚ₂ of the second capacitor 60B.

In this manner, in the second application electrically connecting the specified pad 47 and the gate pad 43, the semiconductor device 10C may be used in modes that differ in the gate-source parasitic capacitance C_{gs}. Accordingly, with the configuration of the present embodiment, the gate-source parasitic capacitance of the semiconductor device 10C may be varied in multiple steps without changing the design of the semiconductor device 10C. More specifically, by choosing whether to connect each of the first specified pad 47A and the second specified pad 47B to the gate pad 43, the gate-source parasitic capacitance of the semiconductor device 10C may be varied in multiple steps.

Advantages

The semiconductor device 10C of the third embodiment has the same advantages as the semiconductor device 10A of the first embodiment. Further, the semiconductor device 10C of the third embodiment has the advantages described below.

(3-1) The specified pad 47 includes the first specified pad 47A and the second specified pad 47B that are not electrically connected to each other. The capacitor 60 includes the first capacitor 60A and the second capacitor 60B. The first capacitor 60A includes the first source-side electrode 61A, electrically connected to the source electrode 28, and the first specified electrode 62C, electrically connected to the first specified pad 47A and arranged facing the first source-side electrode 61A. The second capacitor 60B includes the second source-side electrode 61B, electrically connected to the source electrode 28, and the second specified electrode 62D, electrically connected to the second specified pad 47B and arranged facing the second source-side electrode 61B.

When manufacturing the semiconductor module 100 including the semiconductor device 10C, the gate pad 43 and the first specified pad 47A may be selectively connected, and the gate pad 43 and the second specified pad 47B may be selectively connected. This allows the second application connecting the gate pad 43 and the specified pad 47 to take a mode in which only the first specified pad 47A is connected to the gate pad 43, a mode in which only the second specified pad 47B is connected to the gate pad 43, or a mode in which the first specified pad 47A and the second specified pad 47B are both connected to the gate pad 43. In addition to the first application that electrically disconnects the specified pad 47 and the gate pad 43, such connections allow the gate-source parasitic capacitance to be varied in multiple steps without changing the design of the semiconductor device 10C. Thus, the gate-source parasitic capacitance is adjustable in a finer manner.

(3-2) The first specified electrode 62C includes the first opposing portion 62A1 arranged facing the source pad 41 with part of the insulation layer 12 located in between. The first source-side electrode 61A includes the first opposed portion 41A1 formed by the source pad 41 where the source pad 41 faces the first opposing portion 62A1. The second specified electrode 62D includes the second opposing portion 62A2 arranged facing the source pad 41 with part of the insulation layer 12 located in between. The second source-side electrode 61B includes the second opposed portion 41A2 formed by the source pad 41 where the source pad 41 faces the second opposing portion 62A2.

This configuration allows the first capacitor 60A and the second capacitor 60B to be arranged between the source pad 41 and the semiconductor substrate 11. Thus, the arrangement of the first capacitor 60A and the second capacitor 60B will not enlarge the semiconductor device 10C.

(3-3) The capacitance (first specified capacitance Cₛₚ₁) of the first capacitor 60A is greater than the capacitance (second specified capacitance Cₛₚ₂) of the second capacitor 60B.

This configuration allows the gate-source parasitic capacitance to differ between the mode in which only the first specified pad 47A is connected to the gate pad 43 and the mode in which only the second specified pad 47B is connected to the gate pad 43. Thus, the gate-source parasitic capacitance of the semiconductor device 10C can be varied in additional multiple steps.

(3-4) The opposing area of the first source-side electrode 61A and the first specified electrode 62C is greater than the opposing area of the second source-side electrode 61B and the second specified electrode 62D. This configuration allows the capacitance of the first capacitor 60A to be greater than the capacitance of the second capacitor 60B by simply adjusting the planar shapes of the first opposing portion 62A1 of the first specified electrode 62C and the second opposing portion 62A2 of the second specified electrode 62D.

(3-5) The first specified pad 47A and the second specified pad 47B are arranged sandwiching the source pad 41 on the head surface 12A of the insulation layer 12.

This configuration facilitates connection of the first specified electrode 62C and the first specified pad 47A and connection of the second specified electrode 62D and the second specified pad 47B. Further, the first connecting portion 62B1 of the first specified electrode 62C and the second connecting portion 62B2 of the second specified electrode 62D do not have to be enlarged and may have a simple shape.

(3-6) The first specified pad 47A and the second specified pad 47B are separated from each other in the Y-direction in which the source pad 41 extends, in plan view. The gate pad 43 includes the first gate pad 43A, located next to the first specified pad 47A in the X-direction in plan view, and the second gate pad 43B, located next to the second specified pad 47B in the X-direction in plan view.

In this configuration, the gate pad 43 is divided into two, and the two parts of the gate pad 43 (first gate pad 43A and second gate pad 43B) are respectively located near the first specified pad 47A and the second specified pad 47B. Thus, when using the specified wire 109 to connect the gate pad 43 and the specified pad 47, the first gate pad 43A is connected to the first specified pad 47A. Further, the second gate pad 43B is connected to the second specified pad 47B. This allows the specified wire 109, which connects the gate pad 43 and the specified pad 47, to be shortened.

### Modified Examples

The above embodiments may be modified as described below. The above embodiments and the modified examples described below may be combined as long as there is no technical contradiction. In the modified examples described hereafter, same reference characters are given to those components that are the same as the corresponding components of the above embodiments. Such components will not be described in detail.

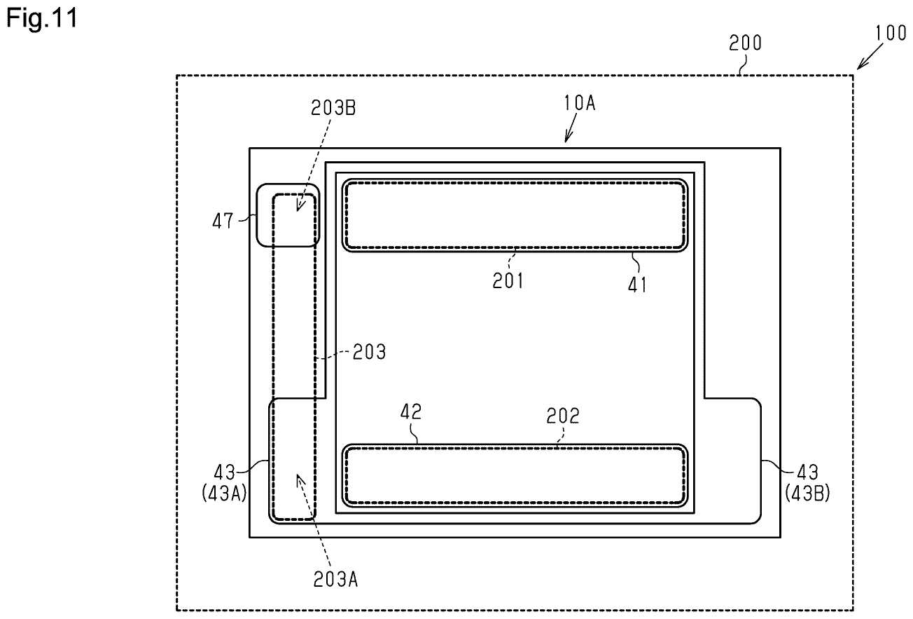

The specified pad 47 and the gate pad 43 do not necessarily have to be connected with the specified wire 109. For example, the semiconductor module 100 may be a chip size package that connects the specified pad 47 and the gate pad 43 without the specified wire 109. FIG. 11 illustrates one example of a configuration that connects the specified pad 47 and the gate pad 43 without using the specified wire 109.

FIG. 11 is a plan view of the semiconductor device 10A mounted on a mounting board 200, such as a printed wiring board, taken from the side of the mounting board 200. FIG. 11 shows the semiconductor device 10A through the mounting board 200, which is illustrated in broken lines.

The mounting board 200 includes a mounting surface on which the semiconductor device 10A is mounted. A first board interconnection 201, a second board interconnection 202, and a third board interconnection 203 are formed on the mounting surface of the mounting board 200. The first board interconnection 201 includes, on the mounting surface of the mounting board 200, a portion facing the source pad 41 of the semiconductor device 10A. The second board interconnection 202 includes, on the mounting surface of the mounting board 200, a portion facing the drain pad 42 of the semiconductor device 10A.

The third board interconnection 203 includes, on the mounting surface of the mounting board 200, a first portion 203A, facing the first gate pad 43A of the semiconductor device 10A, and a second portion 203B, facing the specified pad 47. In this case, the specified pad 47 is electrically connected to the first gate pad 43A (gate pad 43) by the third board interconnection 203 on the mounting board 200.

In the semiconductor device 10B of the second embodiment, the connecting portion 62B of the specified electrode 62 may be the fourth conductive layer L2, which is the same as the opposing portion 62A.

In the semiconductor device 10C of the third embodiment, the capacitor 60 may be three or more capacitors.

The capacitor 60 may be separate from the source-side electrode 61. Further, the capacitor 60 may be arranged at a location other than between the source pad 41 and the semiconductor substrate 11.

FIG. 12 shows a modified example of the capacitor 60 that has a capacitance between the specified pad 47 and the semiconductor substrate 11. The specified electrode 62 of the modified example is formed by the specified pad 47, and the source-side electrode 61 is formed by the third conductive layer L1. The source-side electrode 61 includes a source opposing portion 61C, opposing the specified pad 47 with the insulation layer 12 located in between, and a source connecting portion 61D, extending from the source opposing portion 61C. Part of the source connecting portion 61D is located below the source pad 41. In the section where the source connecting portion 61D and the source pad 41 overlap in the Z-direction, the insulation layer 12 located between the source connecting portion 61D and the source pad 41 includes a via V3 electrically connecting the source connecting portion 61D and the source pad 41. In this case, the capacitor 60 has a capacitance between the specified electrode 62 and the specified pad 47.

In the above modified example, instead of forming the source-side electrode 61 with the third conductive layer L1, the source-side electrode 61 may be formed by the fourth conductive layer L2 (refer to FIG. 9) that is embedded in the insulation layer 12. The capacitor 60 may have a capacitance between the third conductive layer L1 and the fourth conductive layer L2. In this case, one of the third conductive layer L1 and the fourth conductive layer L2 forms the specified electrode 62 that is electrically connected to the specified pad 47. The other one of the third conductive layer L1 and the fourth conductive layer L2 forms the source-side electrode 61 that is electrically connected to the source electrode 28.

The capacitor 60 may be an external capacitor mounted on the source pad 41 and the specified pad 47 outside the insulation layer 12. In this case, one of the two electrodes of the external capacitor connected to the source pad 41 forms the source-side electrode 61. The other one of the two electrodes connected to the specified pad 47 forms the specified electrode 62.

There is no limitation to the planar shape, number, and arrangement of the source pad 41, the drain pad 42, the gate pad 43, and the specified pad 47 on the head surface 12A of the insulation layer 12.

In the first application in which the specified pad 47 and the gate pad 43 are electrically disconnected, instead of the specified pad 47 having a null potential (floating state), the specified pad 47 may be electrically connected to the source pad 41 by a wire or the like. In this case, the potential at the specified pad 47 and the specified electrode 62 is a source potential.

In each of the above embodiments, the transistor T is a HEMT using a nitride semiconductor. The semiconductor device of each embodiment used as the transistor T may be any transistor.

In this specification, the word “on” includes the meaning of “above” in addition to the meaning of “on” unless otherwise described in the context. Accordingly, the phrase of “first layer formed on second layer” may mean that the first layer is formed directly contacting the second layer in one embodiment and that the first layer is located above the second layer without contacting the second layer in another embodiment. Thus, the word “on” will also allow for a structure in which another layer is formed between the first layer and the second layer.

The Z-direction referred to in this specification does not necessarily have to be the vertical direction and does not necessarily have to exactly coincide with the vertical direction. Accordingly, in the structures disclosed above (e.g., structures shown in FIGS. 2 and 3), upward and downward in the Z-direction as referred to in this specification is not limited to upward and downward in the vertical direction. For example, the X-direction may be the vertical direction. Alternatively, the Y-direction may be the vertical direction.

Terms such as “first”, “second”, and “third” in this disclosure are used to distinguish subjects and not used for ordinal purposes.

### Clauses

Technical concepts that can be understood from each of the above embodiments and modified examples will now be described. Reference characters shown in parenthesis in the embodiments described below denote corresponding elements of the embodiments described above. The reference characters are given as examples to aid understanding and not intended to limit elements to the elements denoted by the reference characters.

### [Clause 1]

A semiconductor device (10A, 10B, 10C), including:
a semiconductor substrate (11);
a transistor (T) formed on the semiconductor substrate and including a source electrode (28), a drain electrode (30), and a gate electrode (24);
an insulation layer (12) arranged on the semiconductor substrate (11);
a source pad (41) formed on a head surface (12A) of the insulation layer (12) and electrically connected to the source electrode (28);
a drain pad (42) formed on the head surface (12A) of the insulation layer (12) and electrically connected to the drain electrode (30);
a gate pad (43) formed on the head surface (12A) of the insulation layer (12) and connected to the gate electrode (24);
a specified pad (47) formed on the head surface (12A) of the insulation layer (12); and
a capacitor (60) including a source-side electrode (61), electrically connected to the source electrode (28), and a specified electrode (62), electrically connected to the specified pad (47) and arranged facing the source-side electrode (61).

### [Clause 2]

The semiconductor device (10A, 10B, 10C) according to clause 1, where:
the specified electrode (62) includes an opposing portion (62A, 62A1, 62A2) facing the source pad (41) with part of the insulation layer (12) located in between; and
the source side electrode (61) includes an opposed portion (41A, 41A1, 41A2) formed by the source pad (41) where the source pad (41) faces the opposing portion (62A, 62A1, 62A2).

### [Clause 3]

The semiconductor device (10A, 10B, 10C) according to clause 2, where:
the specified electrode (62) further includes a connecting portion (62B, 62B1, 62B2) electrically connecting the opposing portion (62A, 62A1, 62A2) and the specified pad (47); and
the specified electrode (62) extends across both of the source pad (41) and the specified pad (47) in a view taken in a thickness direction of the semiconductor substrate (11).

### [Clause 4]

The semiconductor device (10A, 10B, 10C) according to clause 3, further including a via (V1) extending through the insulation layer (12) between the connecting portion (62B, 62B1, 62B2) and the specified pad (47) and electrically connecting the connecting portion (62B, 62B1, 62B2) and the specified pad (47).

### [Clause 5]

The semiconductor device (10A, 10C) according to any one of clauses 2 to 4, where the opposing portion (62A, 62A1, 62A2) is formed on a back surface of the insulation layer (12).

### [Clause 6]

The semiconductor device (10B, 10C) according to any one of clauses 2 to 4, where the opposing portion (62A, 62A1, 62A2) is an embedded conductive layer (L2) embedded in the insulation layer (12).

### [Clause 7]

The semiconductor device according to clause 1, where the source-side electrode (61) is separate from the source pad (41).

### [Clause 8]

The semiconductor device (10C) according to any one of clauses 1 to 7, where:
the specified pad (47) includes a first specified pad (47A) and a second specified pad (47B) that are formed, separated from each other, on the head surface (12A) of the insulation layer (12);
the capacitor (60) includes a first capacitor (60A) and a second capacitor (60B);
the first capacitor (60A) includes
   a first source-side electrode (61A) that is the source-side electrode (61) and electrically connected to the source electrode (28), and
   a first specified electrode (62C) that is the specified electrode (62), electrically connected to the first specified pad (47A), and arranged facing the first source-side electrode (61A); and the second capacitor (60B) includes
   a second source-side electrode (61B) that is the source-side electrode (61) and electrically connected to the source electrode (28), and
   a second specified electrode (62D) that is the specified electrode (62), electrically connected to the second specified pad (47B), and arranged facing the second source-side electrode (61B).

### [Clause 9]

The semiconductor device (10C) according to clause 8, where:
the first specified electrode (62C) includes a first opposing portion (62A1) arranged facing the source pad (41) with part of the insulation layer (12) located in between;
the first source-side electrode (61A) includes a first opposed portion (41A1) formed by the source pad (41) where the source pad (41) faces the first opposing portion;
the second specified electrode (62D) includes a second opposing portion (62A2) arranged facing the source pad with part of the insulation layer located in between; and
the second source-side electrode (61) includes a second opposed portion (41A2) formed by the source pad (41) where the source pad (41) faces the second opposing portion (62A2).

### [Clause 10]

The semiconductor device (10C) according to clause 8 or 9, where the first capacitor (60A) has a larger capacitance than the second capacitor (60B).

### [Clause 11]

The semiconductor device (10C) according to any one of clauses 8 to 10, where an opposing area of the first source-side electrode (61A) and the first specified electrode (62C) is larger than an opposing area of the second source-side electrode (61B) and the second specified electrode (62D).

### [Clause 12]

The semiconductor device (10C) according to any one of clauses 8 to 11, where the first specified pad (47A) and the second specified pad (47B) are arranged sandwiching the source pad (41) on the head surface (12A) of the insulation layer (12).

### [Clause 13]

The semiconductor device (10C) according to any one of clauses 8 to 12, where:
the first specified pad (47A) and the second specified pad (47B) are separated from each other in a first direction (Y-direction), in which the source pad (41) extends, in a view taken in a thickness direction (Z-direction) of the semiconductor substrate (11); and
the gate pad (43) includes
   a first gate pad (43A) located next to the first specified pad (47A) in a second direction (X-direction) that is orthogonal to the first direction (Y-direction) in the view taken in the thickness direction (Z-direction) of the semiconductor substrate (11), and
   a second gate pad (43B) located next to the second specified pad (47B) in the second direction (X-direction).

### [Clause 14]

The semiconductor device (10A, 10B, 10C) according to any one of clauses 1 to 13, where the specified pad (47) is located closer to the source pad (41) than the gate pad (43) on the head surface (12A) of the insulation layer (12).

### [Clause 15]

The semiconductor device (10A, 10B, 10C) according to any one of clauses 1 to 14, where the gate pad (43) is located closer to the drain pad (42) than the source pad (41) on the head surface (12A) of the insulation layer (12).

### [Clause 16]

The semiconductor device (10A, 10B, 10C) according to any one of clauses 1 to 15, where:
the transistor (T) includes
   an electron transit layer (16) composed of a nitride semiconductor,
   an electron supply layer (18) formed on the electron transit layer (16) and composed of a nitride semiconductor having a larger band gap than the electron transit layer (16),
   a gate layer (22) formed on part of the electron supply layer (18) and composed of a nitride semiconductor containing an acceptor impurity,
   the gate electrode (24) formed on the gate layer, and
   the source electrode (28) and the drain electrode (30) that are in contact with the electron supply layer (18); and
the gate layer (22) is located between the source electrode (28) and the drain electrode (30) on the electron supply layer (18).

### [Clause 17]

The semiconductor device (10A, 10B, 10C) according to any one of clauses 1 to 16, further including:
an active region (A1) in which the transistor (T) is formed; and
a peripheral region (A2) surrounding the active region (A1),
where the source pad (41) and the drain pad (42) are arranged in the peripheral region (A2) so as to sandwich the active region (A1).

### [Clause 18]

The semiconductor device (10A, 10B, 10C) according to any one of clauses 1 to 17, further including:
source interconnections (44) extending from the source pad (41) toward the drain pad (42); and
drain interconnections (45) extending from the drain pad (42) toward the source pad (41), where:
the source interconnections (44) and the drain interconnections (45) are arranged alternately in a first direction (Y-direction);
the source electrode (28) is connected to the source interconnections (44); and
the drain electrode (30) is connected to the drain interconnections (45).

### [Clause 19]

A semiconductor module (100), including:
a die pad (101);
the semiconductor device (10A, 10B, 10C) according to any one of clauses 1 to 18 mounted on the die pad (101); and
an encapsulation resin (102) that encapsulates the semiconductor device (10A,

### [Clause 20]

The semiconductor module (100) according to clause 19, further including a specified wire (109) connecting the specified pad (47) and the gate pad (43).

### [Clause 21]

The semiconductor module (100) according to clause 18 or 19, where the specified pad (47) is electrically disconnected from the gate pad (43).

### [Clause 22]

The semiconductor module (100) according to any one of clauses 18 to 21, further including:
a source lead (103), a drain lead (104), and a gate lead (105);
a source wire (106) connecting the source lead (103) and the source pad (41);
a drain wire (107) connecting the drain lead (104) and the drain pad (42); and
a gate wire (108) connecting the gate lead (105) and the gate pad (43).

Various changes in form and details may be made to the examples above without departing from the spirit and scope of the claims and their equivalents. The examples are for the sake of description only, and not for purposes of limitation. Descriptions of features in each example are to be considered as being applicable to similar features or aspects in other examples. Suitable results may be achieved if sequences are performed in a different order, and/or if components in a described system, architecture, device, or circuit are combined differently, and/or replaced or supplemented by other components or their equivalents. The scope of the disclosure is not defined by the detailed description, but by the claims and their equivalents. All variations within the scope of the claims and their equivalents are included in the disclosure.

What is claimed is:

1. A semiconductor device, comprising:
a semiconductor substrate;
a transistor formed on the semiconductor substrate and including a source electrode, a drain electrode, and a gate electrode;
an insulation layer arranged on the semiconductor substrate;
a source pad formed on a head surface of the insulation layer and electrically connected to the source electrode;
a drain pad formed on the head surface of the insulation layer and electrically connected to the drain electrode;
a gate pad formed on the head surface of the insulation layer and connected to the gate electrode;
a specified pad formed on the head surface of the insulation layer; and
a capacitor including a source-side electrode, electrically connected to the source electrode, and a specified electrode, electrically connected to the specified pad and arranged facing the source-side electrode.

2. The semiconductor device according to claim 1, wherein:
the specified electrode includes an opposing portion facing the source pad with part of the insulation layer located in between; and
the source side electrode includes an opposed portion formed by the source pad where the source pad faces the opposing portion.

3. The semiconductor device according to claim 2, wherein:
the specified electrode further includes a connecting portion electrically connecting the opposing portion and the specified pad; and
the specified electrode extends across both of the source pad and the specified pad in a view taken in a thickness direction of the semiconductor substrate.

4. The semiconductor device according to claim 3, further comprising a via extending through the insulation layer between the connecting portion and the specified pad and electrically connecting the connecting portion and the specified pad.

5. The semiconductor device according to claim 2, wherein the opposing portion is formed on a back surface of the insulation layer.

6. The semiconductor device according to claim 2, wherein the opposing portion is an embedded conductive layer embedded in the insulation layer.

7. The semiconductor device according to claim 1, wherein:
the specified pad includes a first specified pad and a second specified pad that are formed, separated from each other, on the head surface of the insulation layer;
the capacitor includes a first capacitor and a second capacitor;
the first capacitor includes
a first source-side electrode that is the source-side electrode and electrically connected to the source electrode, and
a first specified electrode that is the specified electrode, electrically connected to the first specified pad, and arranged facing the first source-side electrode; and
the second capacitor includes
a second source-side electrode that is the source-side electrode and electrically connected to the source electrode, and
a second specified electrode that is the specified electrode, electrically connected to the second specified pad, and arranged facing the second source-side electrode.

8. The semiconductor device according to claim 7, wherein:
the first specified electrode includes a first opposing portion arranged facing the source pad with part of the insulation layer located in between;
the first source-side electrode includes a first opposed portion where the source pad faces the first opposing portion;
the second specified electrode includes a second opposing portion arranged facing the source pad with part of the insulation layer located in between; and
the second source-side electrode includes a second opposed portion where the source pad faces the second opposing portion.

9. The semiconductor device according to claim 7, wherein the first capacitor has a larger capacitance than the second capacitor.

10. The semiconductor device according to claim 7, wherein an opposing area of the first source-side electrode and the first specified electrode is larger than an opposing area of the second source-side electrode and the second specified electrode.

11. The semiconductor device according to claim 7, wherein the first specified pad and the second specified pad are arranged sandwiching the source pad on the head surface of the insulation layer.

12. The semiconductor device according to claim 7, wherein:
the first specified pad and the second specified pad are separated from each other in a first direction, in which the source pad extends, in a view taken in a thickness direction of the semiconductor substrate; and
the gate pad includes
a first gate pad located next to the first specified pad in a second direction that is orthogonal to the first direction in the view taken in the thickness direction of the semiconductor substrate, and
a second gate pad located next to the second specified pad in the second direction.

13. The semiconductor device according to claim 1, wherein the specified pad is located closer to the source pad than the gate pad on the head surface of the insulation layer.

14. The semiconductor device according to claim 1, wherein the gate pad is located closer to the drain pad than the source pad on the head surface of the insulation layer.

15. The semiconductor device according to claim 1, wherein:
the transistor includes
an electron transit layer composed of a nitride semiconductor,
an electron supply layer formed on the electron transit layer and composed of a nitride semiconductor having a larger band gap than the electron transit layer,
a gate layer formed on part of the electron supply layer and composed of a nitride semiconductor containing an acceptor impurity,
the gate electrode formed on the gate layer, and
the source electrode and the drain electrode that are in contact with the electron supply layer; and
the gate layer is located between the source electrode and the drain electrode on the electron supply layer.

16. A semiconductor module, comprising:
the semiconductor device according to claim 1; and
an encapsulation resin encapsulating the semiconductor device.

17. The semiconductor module according to claim 16, further comprising a specified wire connecting the specified pad and the gate pad.

18. The semiconductor module according to claim 16, wherein the specified pad is electrically disconnected from the gate pad.

19. The semiconductor module according to claim 16, comprising:
a source lead, a drain lead, and a gate lead;
a source wire connecting the source lead and the source pad;
a drain wire connecting the drain lead and the drain pad; and
a gate wire connecting the gate lead and the gate pad.
